(19) United States
(12) Patent Application Publication
(10) Pub. No.: US 2008/0118734 A1
(43) Pub. Date: May 22, 2008

(54) Coating Compositions

(75) Inventors: Andrew James Goodwin, Roachestown Co Cork (IE); Stuart Robert Leadley, Midleton, Co Cork (IE); Liam O'Neill, Riverstown Co Cork (IE); Paul John Duffield, Hull (GB); Malcolm Tom McKechnie, Hull (GB); Simon Pugh, Hull (GB)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(73) Assignee: DOW CORNING IRELAND LTD., Midleton, Co Cork, IE (IE)

(21) Appl. No.: 11/569,100

(22) PCT Filed: May 13, 2005
(86) PCT No.: PCT/GB05/01828

§ 371 Date: Aug. 15, 2007

(30) Foreign Application Priority Data
May 14, 2004 (GB) 0410749.6

(51) Int. Cl. C23C 16/513

(52) U.S. Cl. 428/221; 427/569; 427/535; 427/578

(57) ABSTRACT

A method for forming an active material containing coating on a substrate, which method comprises the steps of: i) introducing one or more gaseous or atomised liquid and/or solid coating-forming materials which undergo chemical bond forming reactions within a plasma environment and one or more active materials which substantially do not undergo chemical bond forming reactions within a plasma environment, into an atmospheric or low pressure non-thermal equilibrium plasma discharge and/or an excited gas stream resulting therefrom, and ii) exposing the substrate to the resulting mixture of atomised coating-forming and at least one active material which are deposited onto the substrate surface to form a coating; wherein the substrate is not a wipe, cloth or sponge for household care or depilatory care or a water solute household cleaning unit dose product.

The present invention relates to a process for incorporating one or more active materials in coating compositions obtained through plasma polymerisation or plasma enhanced chemical vapour deposition (PE-CVD).

The term Active material(s) as used herein is intended to mean one or more materials that perform one or more specific functions when present in a certain environment and in the case of the present application they are chemical species which do not undergo chemical bond forming reactions within a plasma environment. It is to be appreciated that an active material is clearly discriminated from the term “Reactive”. A reactive material or chemical species is intended to mean a species which undergoes chemical bond forming reactions within a plasma environment. The active may of course be capable of undergoing a reaction after the coating process.

Active materials are often present in formulated products in low concentrations and yet are typically the most costly component in the formulated product. For example, the UV absorbing or refracting component of a sun block emulsion formulated product or the decongestant and/or analgesic in a cold cure formulated product. Ensuring effective delivery of the active to the point of end application is a key requirement for good efficacy of the product.

Active materials often need to be protected during processing and prior to end use in order that they are safely released and or activated or the like at the intended point of end use for both effective performance and effective cost. This is often achieved by incorporating the active into a protective matrix, applying a protective coating, or introducing the active into a matrix in a chemically protected form (i.e. the presence of protective end groups which will react with another species in the end use environment to release the active). The two former protective methods may be referred to in general terms as forms of encapsulation. For example many pharmaceutical materials are susceptible to acidic degradation and need to be protected from the acidic stomach prior to effective release and adsorption in the more alkaline intestine. In this case the encapsulating coatings are known as enteric coatings. Other additives must be protected from heat, moisture, or extremes of pH during processing as part of incorporation into the product matrix.

As well as protecting an active prior to and/or during delivery the encapsulating coating or matrix may also serve as a mechanism to control release of the active. This controlled release or sustained release ensures a controlled dosage of the active for a prolonged period of time. Controlled release is typically a diffusion-controlled process where the active diffuses through the encapsulating matrix or coating or the encapsulating material gradually dissolves in the environment in which the active is to be released.

Polymer matrices and polymeric coatings are often used as media for encapsulation and controlled release. A wide range of polymeric materials has been used for this purpose from natural macromolecules such as cellulose through to synthetic polymers such as polymers of methacrylic acid and methacrylate such as the EUDRAGIT® range of products for enteric coatings from Degussa. In the case of coatings, these are often applied from solvent using traditional coating processes.

Polymeric coatings are widely used throughout industry because they are easily applied, to give conformal, filmic coatings on a wide range of substrates. The functionality of the polymer, for example, oil repellency, water barrier, biocompatibility, decorative, adhesive, release etc. is often provided to the substrate coated. An extensive range of methods are used for the delivery and/or curing of films or the like made from the polymeric coatings. As an example a polymer melt or solution is typically applied by mechanical coating or immersion of a substrate with the resulting polymeric coating being converted to a film by a suitable curing technique such as for example by the application of heat, radiation and/or pressure. More recently it has been demonstrated that thin, conformal polymeric films can be applied/deposited on substrates by means of plasma polymerisation or plasma enhanced chemical vapour deposition (PE-CVD) processes.

Conformal polymer films can be applied via the process of plasma polymerisation or plasma enhanced chemical vapour deposition (PE-CVD). Chemical Vapour Deposition is the deposition of a solid on a heated substrate from a chemical reaction in the vapour phase near or on the heated substrate. The chemical reactions that take place may include thermal decomposition, oxidation, carburisation and nitridation. Typically the sequence of events for a CVD reaction comprises the following sequentially: —
i) Introduction of reactant gases into a reactor by appropriate introduction means e.g. forced flow,
ii) diffusion of the gases through the reactor towards a substrate surface
iii) contact of gases with substrate surface
iv) chemical reaction takes place between gases and/or one or more gases and the substrate surface
v) desorption and diffusion away from substrate surface of reaction by-products.

The term “plasma” covers a wide range of systems whose density and temperature vary by many orders of magnitude. Some plasmas are very hot and all their microscopic species (ions, electrons, etc.) are in approximate thermal equilibrium, the energy input into the system being widely distributed through atomic/molecular level collisions, examples include a flame and plasma spray techniques involving the blasting of surfaces with molten solids at very high temperatures. Other plasmas, however, such as those at low pressure (e.g. 100 Pa) where collisions are relatively infrequent, have their constituent species at widely different temperatures and are called “non-thermal equilibrium” plasmas. In these non-thermal plasmas, free electrons are very hot with temperatures of many thousands of Kelvin (K) whilst the neutral and ionic species remain cool. Because the free electrons have almost negligible mass, the total system heat content is low and the plasma operates close to room temperature thus allowing the processing of temperature sensitive materials, such as plastics or polymers, without imposing a damaging thermal burden onto the sample. However, the hot electrons create, through high energy collisions, a rich source of radicals and excited species with a high chemical potential energy capable of profound chemical and physical reactivity.

Non-thermal equilibrium plasmas processes are ideal for the coating of substrates in the form of delicate and heat sensitive webbed materials because generally the resulting coatings are free of micropores even with thin layers. The optical properties, e.g. colour, of the coating can often be customised and plasma coatings adhere well to even non-polar materials, e.g. polyethylene, as well as steel (e.g. anti-corrosion films on metal reflectors), textiles, etc.

In the case of plasma enhanced CVD the gases are directed so as to diffuse through plasma. Any appropriate plasma may be utilised. Non-thermal equilibrium plasma such as for example glow discharge plasma may be utilised. The glow discharge may be generated at low pressure, i.e. vacuum glow discharge or in the vicinity of atmospheric pressure—atmospheric pressure glow discharge, however in respect of the present invention the latter is preferred. Homogeneous diffuse dielectric barrier discharge such as Glow discharge plasma is generated in a gas, such as helium by a high frequency electric field.

Typically the plasma is generated in a gap between two electrodes, at least one of which is encased or coated or the like in a dielectric material. PE-CVD may be utilised at any suitable temperature e.g. a plasma at a temperature of from room temperature to 500° C.

Yasuda, H Plasma Polymerization; Academic Press: Orlando, 1985 describes how vacuum glow discharge has been used to polymerise gas phase polymer precursors into continuous films. As an example, the plasma enhanced surface treatment and deposition of fluorocarbons has been investigated for the preparation of oleophobic surfaces since the 1970's. Initially, simple fluorocarbon gas precursors such as carbon tetrafluoride were used; this improved hydrophobicity but did not significantly improve oleophobicity. Subsequently, as described in EP 0049884 higher molecular weight fluorinated precursors such as the perfluoroalkyl substituted acrylates were used.

These early processes typically resulted in fragmentation of the precursor and insertion of fluorine into the surface rather than formation of a polymerised fluorocarbon coating. The development of pulsed plasma polymerization (or modulated discharge) as described in Ryan, M, Hynes, A, Badyal, J, Chem. Mater., 1996, 8(1), 37-42 and Chen, X, Rajeshwar, K, Timmons, R, Chen, J, Chyan, O, Chem. Mater., 1996, 8(5), 1067-77 produced polymerised coatings in which the properties and/or functionalities of the monomer are substantially retained resulting in the production of a polymeric coating retaining many properties of the bulk polymer. Coulson S R, Woodward I S, Badyal J P S, Brewer S A, Willis C, Langmuir, 16, 6287-6293, (2000) describe the production of highly oleophobic surfaces using long chain perfluoroacrylate or perfluoroalkene precursors.

Vacuum glow discharge processes have been investigated as routes to encapsulation and controlled release for example Colter, K D; Shen, M; Bell, A T Biomaterials, Medical Devices, and Artificial Organs (1977), 5(1), 13-24 describes a method where fluoropolymer coatings are applied to reduce the diffusion of a steroid active through a polydimethylsiloxane elastomer. Kitade, Tatsuya; Kitamura, Keisuke; Hozumi, Kei. Chemical & Pharmaceutical Bulletin (1987), 35(11), 4410-17 describes the application of vacuum glow discharge plasma to coat a powdered active with a PTFE based coating for controlled dissolution. WO 9910560 describes a further vacuum plasma method where precursor vapour is introduced to the plasma to produce coatings for the purpose of encapsulation.

Two significant drawbacks exist for vacuum plasma methods, firstly the necessity for a vacuum requires the coating process to be operated in a batch wise format, secondly the active must be introduced into the plasma as a vapour if the vacuum is to be maintained or the active is coated by conventional means and then in a separate step coated with an encapsulating plasma coating.

One type of plasma is generally referred to as diffuse dielectric barrier discharge (one form of which can be referred to as an atmospheric pressure glow discharge Sherman, D. M. et al, J. Phys. D.; Appl. Phys. 2005, 38 547-554). This term is generally used to cover both glow discharges and dielectric barrier discharges whereby the breakdown of the process gas occurs uniformly across the plasma gap resulting in an homogeneous plasma across the width and length of a plasma chamber. (Kogelschatz, U. 2002 “Filamentary, patterned, and diffuse barrier discharges” IEEE Trans. Plasma Sci. 30, 1400-8). These may be generated at both vacuum and atmospheric pressures. In the case of atmospheric pressure diffuse dielectric barrier discharges, gases including helium, argon or nitrogen are utilised as process gases for generating the plasma and a high frequency (e.g. >1 kHz) power supply is used to generate a homogeneous or uniform plasma between the electrodes at atmospheric pressure. The exact mechanism of formation of diffuse DBD is still a matter of debate but there is mounting evidence that Penning ionisation plays a critical role, in combination with secondary electron emission from the cathode surface. (See for example, Kanazawa et al, J. Phys. D: Appl. Phys. 1988, 21, 838, Okazaki et al, Proc. Jpn. Symp. Plasma Chem. 1989, 2, 95, Kanazawa et al, Nuclear Instruments and Methods in Physical Research 1989, B37/38, 842, and Yokoyama et al., J. Phys. D: Appl. Phys. 1990, 23, 374). Atmospheric pressure diffuse dielectric discharge processes such as Atmospheric Pressure Glow Discharge (APGD) offer an alternative homogeneous plasma source, which have many of the benefits of vacuum plasma methods, while operating at atmospheric pressure or thereabouts. The use of APGD was significantly developed in the 1980's, e.g. as described in Kanazawa S, Kogoma M, Moriwaki T, Okazaki S, J. Phys. D: Appl. Phys., 21, 838-840 (1988) and Roth J R, Industrial Plasma Engineering Volume 2 Applications to Nonthermal Plasma Processing, Institute of Physics Publishing, 2001, pages 37-73. WO 01 59809 and WO 02 35576 describe a series of wide area APGD systems, which provide a uniform, homogeneous plasma at ambient pressure by application of a low frequency RF voltage across opposing parallel plate electrodes separated by ˜10 mm. The ambient pressure and temperature ensures compatibility with open perimeter, continuous, on-line processing.

Considerable work has been done on the stabilisation of atmospheric pressure glow discharges, described in “Appearance of stable glow discharge in air, argon, oxygen and nitrogen at atmospheric pressure using a 50 Hz source” by Satiko Okazaki, Masuhiro Kogoma, Makoto Uehara and Yoshihisa Kimura, J. Phys. D: Appl. Phys. 26 (1993) 889-892. Further, there is described in U.S. Pat. No. 5,414,324 (Roth et al) the generation of a steady-state glow discharge plasma at atmospheric pressure between a pair of insulated metal plate electrodes spaced up to 5 cm apart and radio frequency (RF) energised with a root mean square (rms) potential of 1 to 5 kV at 1 to 100 kHz. This patent specification describes the use of electrically insulated metallic plate electrodes. This patent specification also describes a number of problems relating to the use of plate electrodes and the need to discourage electrical breakdown at the tips of electrodes.

These ambient temperature, atmospheric plasma systems have also been used to demonstrate the deposition of plasma coatings from vapour phase monomers—in effect atmospheric PE-CVD. For example EP 0431951 describes surface treatment with silane and disilane vapour and U.S. Pat. No. 6,146,724 describes the deposition of a barrier coating from siloxane vapour precursors.

WO 02/28548 describes a process for enabling the introduction of a solid or liquid precursor into an atmospheric pressure plasma discharge and/or an ionised gas stream resulting therefrom in order to form a coating on a substrate, where the substrate comprises metal, ceramic, plastic, woven or non-woven fibres, natural fibres, synthetic fibres, cellulosic material and powders. The invention describes how the chemical properties of the reactive coating precursor are substantially retained.

In accordance with the present invention there is provided a method for forming an active material containing coating on a substrate, which method comprises the steps of: —
i) introducing one or more gaseous or atomised liquid and/or solid coating-forming materials which undergo chemical bond forming reactions within a plasma environment and one or more active materials which substantially do not undergo chemical bond forming reactions within a plasma environment, into an atmospheric or low pressure non-thermal equilibrium plasma discharge and/or an excited gas stream resulting therefrom, and
ii) exposing the substrate to the resulting mixture of atomised coating-forming and at least one active material which are deposited onto the substrate surface to form a coating;
   wherein the substrate is not a wipe, cloth or sponge for household care or depilatory care or a water soluble household cleaning unit dose product.

The resulting coating which is prepared comprises a coating of the substrate comprising a coating made from the plasma activated coating derived from the coating forming material having particles/molecules of the active material trapped/encapsulated within the coating.

Preferably the plasma utilised is at substantially atmospheric pressure. Preferably the plasma is generated at any suitable temperature, it preferably operates at a temperature between room temperature (20° C.) and 300° C. and typically, in the case of diffuse dielectric barrier discharge processes, is utilized at a temperature in the region of 30 to 50° C. Whilst the temperature of activated electrons may be individually >1000° C., the system as a whole must operate at a temperature sufficiently low not to disintegrate or deactivate either the trapped active species or the coating material which in many cases are heat sensitive. Hence the process cannot be carried out at high temperatures using, for example, flame treatment systems (thermal equilibrium plasmas) which operate at significantly greater than 300° C., i.e. >1000° C. gas temperature. Flame systems such as plasma guns used to melt solid particles and create a coating by “blasting” a surface are not suitable as they are oxidative by nature which means they have significant limitations when applied to deposition processes. In such high temperature gases it is impossible to maintain the chemical structure and/or functionality of the precursor in the deposited coatings.

Any suitable active material may be utilised providing it substantially does not undergo chemical bond forming reactions within a plasma. Examples of suitable active materials include anti-microbials (for example, quaternary ammonium and silver based), enzymes, proteins, DNA/RNA, pharmaceutical materials, UV screen, anti-oxidant, flame retardant, cosmeceuticals, therapeutic or diagnostic materials antibiotics, anti-bacterials, anti-fungals, cosmetics, cleansers, growth factors, aloe, and vitamins, fragrances & flavours; agrochemicals (pheromones, pesticides, herbicides), dyestuffs and pigments, for example photochromic dyestuffs and pigments and catalysts.

The chemical nature of the active material(s) used in the present invention is/are generally not critical. They can comprise any solid or liquid material which can be bound in the composition and where appropriate subsequently released at a desired rate.

Therapeutically active materials which may be employed include, for example, anti-acne agent, antibiotic, antiseptic, anti-fungal, anti-bacterial, anti-microbial, biocides, anti-inflammatory, hyluronic acid containing materials, astringents, hormones, anti-cancer agents, smoking cessation compositions, cardiovascular, histamine blocker, bronchodilator, analgesic, anti-arrythmic, anti-histamine, alpha-I blocker, beta blocker, ACE inhibitor, diuretic, anti-aggregant, sedative, tranquilizer, anti-convulsant, anti-coagulant agents, vitamins, anti-aging agents, agents for treating gastric and duodenal ulcers, anti-cellulites, proteolytic enzymes, healing factors, cell growth nutrients, peptides and others. Specific examples of suitable therapeutic active materials include penicillins, cephalosporins, tetracyclines, macrolides, epinephrine, amphetamines, aspirin, acetominophen, barbiturates, catecholamines, benzodiazepine, thiopental, codeine, morphine, procaine, lidocaine, benzocaine, sulphonamides, ticonazole, perbuterol, furosamide, prazosin, prostaglandins, salbutamol, indomethicane, diclofenac, glafenine, dipyridamole, theophylline and retinol.

The active materials may comprise nanoparticles, particularly nanotubes. The term nanotube as used in this patent specification is taken to mean any nanostructure and related materials. The nanotubes can be in the form of carbon nanotubes, nanotubes of other materials such as vanadium pentoxide for example, nanostructures (regular and undefined), as well as derivatives of these which can be based on or contain, as an example, Silicon, Boron, Tin, nitrogen, compounds of vanadium and oxygen such as vanadium pentoxide, etc. The nanostructures can have dimensions from nanometres in length to millimetres in length, as well as nanometres in width to micrometers in width. The active material(s) may comprise non-toxic cleansers for example in a nanoparticulate form such as nanoparticles of para-chloro-meta-xylenol (PCMX) non-toxic cleanser.

In addition to the therapeutic or diagnostic materials, active materials could be ingredients in cosmetics such as perfumes & fragrances, UV protectors, shaving products, deodorants or the like. Suitable cosmetics are known to those skilled in the art. Examples of the cosmetics, personal care (other than in relation to depilatory devices), and cosmeceutical ingredients and pharmaceutical excipients that may be used herein may be found in the CTFA ingredient Database and the handbook of pharmaceutical excipients and can include, for example, absorbents, anti-caking materials, anti-oxidants, anti-static materials, astringents, binders, buffering materials, bulking materials, chelating materials, colorants, cosmetic astringents, cosmetic biocides, deodorant materials, emollients, external analgesics, film formers, flavouring materials, fragrance ingredients, humectants, lytic materials, moisturizing materials, occlusivity enhancers, opacifying materials, oxidizing and reducing materials, penetration enhancers, pesticides, plasticizers, preservatives, skin bleaching materials, skin conditioning materials, skin protectants, slip modifiers, solubilizing materials, solvents, sunscreen materials, surface modifiers, surfactants and emulsifying materials, suspending materials, thickening materials, viscosity controlling materials including increasing or decreasing materials, UV light absorbers,

Cosmetic, personal care (other than depilatory care) and cosmeceutical ingredients, and pharmaceutical excipients which may be employed as the active material in a composition in accordance with the present invention include for example: alcohols, fatty alcohols and polyols, aldehydes, alkanolamines, alkoxylated alcohols (e.g. polyethylene glycol derivatives of alcohols and fatty alcohols), alkoxylated amides, alkoxylated amines, alkoxylated carboxylic acids, amides including salts (e.g. ceramides), amines, amino acids including salts and alkyl substituted derivatives, esters, alkyl substituted and acyl derivatives, polyacrylic acids, acrylamide copolymers, adipic acid copolymers, alcohols, aminosilicones, biological polymers and derivatives, butylene copolymers, carbohydrates (e.g. polysaccharides, chitosan and derivatives), carboxylic acids, carbomers, esters, ethers and polymeric ethers (e.g. PEG derivatives, PPG derivatives), glyceryl esters and derivatives, halogen compounds, heterocyclic compounds including salts, hydrophilic colloids and derivatives including salts and gums (e.g. cellulose derivatives, gelatin, xanthan gum, natural gums), imidazolines, inorganic materials (clay, TiO2, ZnO), ketones (e.g. camphor), isothionates, lanolin and derivatives, organic salts, phenols including salts (e.g. parabens), phosphorus compounds (e.g. phosphate derivatives), polyacrylates and acrylate copolymers, protein and enzymes derivatives (e.g. collagen), synthetic polymers including salts, siloxanes and silanes, sorbitan derivatives, sterols, sulphonic acids and derivatives and waxes.

Some examples of anti-acne materials, which may be utilized as the active material in a composition in accordance with the present invention, include Salicylic acid and Sulphur. Some examples of anti-fungal materials are Calcium Undecylenate, Undecylenic Acid, Zinc Undecylenate, and Povidone-Iodine. Some examples of anti-microbial materials are Alcohol, Benzalkonium Chloride, Benzethonium Chloride, Methylbenzethonium Chloride, Phenol, Poloxamer 188, and Povidone-Iodine.

Some examples of antioxidants which may be utilized as the active material in a composition in accordance with the present invention include Acetyl Cysteine, Arbutin, Ascorbic Acid, Ascorbic Acid Polypeptide, Ascorbyl Dipalmitate, Ascorbyl Methylsilanol Pectinate, Ascorbyl Palmitate, Ascorbyl Stearate, BHA, p-Hydroxyanisole, BHT, t-Butyl Hydroquinone, Caffeic Acid, Camellia Sinensis Oil, Chitosan Ascorbate, Chitosan Glycolate, Chitosan Salicylate, Chlorogenic Acids, Cysteine, Cysteine HCl, Decyl Mercaptomethylimidazole, Erythorbic Acid, Diamylhydroquinone, Di-t-Butylhydroquinone, Dicetyl Thiodipropionate, Dicyclopentadiene/t-Butylcresol Copolymer, Digalloyl Trioleate, Dilauryl Thiodipropionate, Dimyristyl Thiodipropionate, Dioleyl Tocopheryl Methylsilanol, Isoquercitrin, Diosmine, Disodium Ascorbyl Sulphate, Disodium Rutinyl Disulphate, Distearyl Thiodipropionate, Ditridecyl Thiodipropionate, Dodecyl Gallate, Ethyl Ferulate, Ferulic Acid, Hydroquinone, Hydroxylamine HCl, Hydroxylamine Sulphate, Isooctyl Thioglycolate, Kojic Acid, Madecassicoside, Magnesium Ascorbate, Magnesium Ascorbyl Phosphate, Melatonin, Methoxy-PEG-7 Rutinyl Succinate, Methylene Di-t-Butylcresol, Methylsilanol Ascorbate, Nordihydroguaiaretic Acid, Octyl Gallate, Phenylthioglycolic Acid, Phloroglucinol, Potassium Ascorbyl Tocopheryl Phosphate, Thiodiglycolamide, Potassium Sulphite, Propyl Gallate, Rosmarinic Acid, Rutin, Sodium Ascorbate, Sodium Ascorbyl/Cholesteryl Phosphate, Sodium Bisulphite, Sodium Erythorbate, Sodium Metabisulphide, Sodium Sulphite, Sodium Thioglycolate, Sorbityl Furfural, Tea Tree (Melaleuca Aftemifolia) Oil, Tocopheryl Acetate, Tetrahexyldecyl Ascorbate, Tetrahydrodiferuloylmethane, Tocopheryl Linoleate/Oleate, Thiodiglycol, Tocopheryl Succinate, Thiodiglycolic Acid, Thioglycolic Acid, Thiolactic Acid, Thiosalicylic Acid, Thiotaurine, Retinol, Tocophereth-5, Tocophereth-10, Tocophereth-12, Tocophereth-18, Tocophereth-50, Tocopherol, Tocophersolan, Tocopheryl Linoleate, Tocopheryl Nicotinate, Tocoquinone, o-Tolyl Biguanide, Tris(Nonylphenyl)Phosphite, Ubiquinone, and Zinc Dibutyldithiocarbamate.

Some examples of biocides are Aluminium Phenolsulphonate, Ammonium Phenolsulphonate, Bakuchiol, Benzalkonium Bromide, Benzalkonium Cetyl Phosphate, Benzalkonium Chloride, Benzalkonium Saccharinate, Benzethonium Chloride, Potassium Phenoxide, Benzoxiquine, Benzoxonium Chloride, Bispyrithione, Boric Acid, Bromochlorophene, Camphor Benzalkonium Methosulphate, Captan, Cetalkonium Chloride, Cetearalkonium Bromide, Cetethyldimonium Bromide, Cetrimonium Bromide, Cetrimonium Chloride, Cetrimonium Methosulphate, Cetrimonium Saccharinate, Cetrimonium Tosylate, Cetylpyridinium Chloride, Chloramine T, Chlorhexidine, Chlorhexidine Diacetate, Chlorhexidine Digluconate, Chlorhexidine Dihydrochloride, p-Chloro-m-Cresol, Chlorophene, p-Chlorophenol, Chlorothymol, Chloroxylenol, Chlorphenesin, Ciclopirox Olamine, Climbazole, Cloflucarban, Clotrimazole, Coal Tar, Colloidal Sulphur, o-Cymen-5-ol, Dequalinium Acetate, Dequalinium Chloride, Dibromopropamidine Diisethionate, Dichlorobenzyl Alcohol, Dichlorophene, Dichlorophenyl Imidazoldioxolan, Dichloro-m-Xylenol, Diiodomethyltolylsulphone, Dimethylol Ethylene Thiourea, Diphenylmethyl piperazinylbenzimidazole, Domiphen Bromide, 7-Ethylbicyclooxazolidine, Fluorosalan, Formaldehyde, Glutaral, Hexachlorophene, Hexamidine, Hexamidine Diisethionate, Hexamidine Diparaben, Hexamidine Paraben, Hexetidine, Hydroxymethyl Dioxoazabicyclooctane, Ichthammol, Isopropyl Cresol, Lapyrium Chloride, Lauralkonium Bromide, Lauralkonium Chloride, Laurtrimonium Bromide, Laurtrimonium Chloride, Laurtrimonium Trichlorophenoxide, Lauryl Isoquinolinium Bromide, Lauryl Isoquinolinium Saccharinate, Laurylpyridinium Chloride, Mercuric Oxide, Methenamine, Methenammonium Chloride, Methylbenzethonium Chloride, Myristalkonium Chloride, Myristalkonium Saccharinate, Myrtrimonium Bromide, Nonoxynol-9 Iodine, Nonoxynol-12 Iodine, Olealkonium Chloride, Oxyquinoline, Oxyquinoline Benzoate, Oxyquinoline Sulphate, PEG-2 Coco-Benzonium Chloride, PEG-10 Coco-Benzonium Chloride, PEG-6 Undecylenate, PEG-8 Undecylenate, Phenol, o-Phenylphenol, Phenyl Salicylate, Piroctone Olamine, Sulphosuccinylundecylenate, Potassium o-Phenylphenate, Potassium Salicylate, Potassium Troclosene, Propionic Acid, PVP-Iodine, Quaternium-8, Quaternium-14, Quaternium-24, Sodium Phenolsulphonate, Sodium Phenoxide, Sodium o-Phenylphenate, Sodium Shale Oil Sulphonate, Sodium Usnate, Thiabendazole, 2,2′-Thiobis(4-Chlorophenol), Thiram, Triacetin, Triclocarban, Triclosan, Trioctyidodecyl Borate, Undecylenamidopropylamine Oxide, Undecyleneth-6, Undecylenic Acid, Zinc Acetate, Zinc Aspartate, Zinc Borate, Zinc Chloride, Zinc Citrate, Zinc Cysteinate, Zinc Dibutyldithiocarbamate, Zinc Gluconate, Zinc Glutamate, Zinc Lactate, Zinc Phenolsulphonate, Zinc Pyrithione, Zinc Sulphate, Carbendazim, Copper, Cybutryne, 3-(3,4-dichlrorphenyl)-1,1-dimethylurea, 3-iodo-2-propylnyl butyl carbamate, 2-n-octyl-4-isothiazolin-3-one and 2,4,5,6-tetrachloroisophthalonitrileand Zinc Undecylenate.

Some examples of external analgesics which may be utilized as the active material in a composition in accordance with the present invention include Benzyl Alcohol, Capsicum Oleoresin (Capsicum Frutescens Oleoresin), Methyl Salicylate, Camphor, Phenol, Capsaicin, Juniper Tar (Juniperus Oxycedrus Tar), Phenolate Sodium (Sodium Phenoxide), Capsicum (Capsicum Frutescens), Menthol, Resorcinol, Methyl Nicotinate, and Turpentine Oil (Turpentine).

Some examples of oxidizing materials which may be utilized as the active material in a composition in accordance with the present invention include Ammonium Persulphate, Potassium Bromate, Potassium Caroate, Potassium Chlorate, Potassium Persulphate, Sodium Bromate, Sodium Chlorate, Sodium Iodate, Sodium Perborate, Sodium Persulphate and, Strontium Dioxide.

Some examples of reducing materials which may be utilized as the active material in a composition in accordance with the present invention include Ammonium Bisulphite, Ammonium Sulphite, Ammonium Thioglycolate, Ammonium Thiolactate, Cystemaine HCl, Cystein, Cysteine HCl, Ethanolamine Thioglycolate, Glutathione, Glyceryl Thioglycolate, Glyceryl Thioproprionate, Hydroquinone, p-Hydroxyanisole, Isooctyl Thioglycolate, Magnesium Thioglycolate, Mercaptopropionic Acid, Potassium Metabisulphite, Potassium Sulphite, Potassium Thioglycolate, Sodium Bisulphite, Sodium Hydrosulphite, Sodium Hydroxymethane Sulphonate, Sodium Metabisulphite, Sodium Sulphite, Sodium Thioglycolate, Strontium Thioglycolate, Superoxide Dismutase, Thioglycerin, Thioglycolic Acid, Thiolactic Acid, Thiosalicylic Acid, and Zinc Formaldehyde Sulphoxylate.

An example of a skin bleaching material which may be utilized as the active material in a composition in accordance with the present invention includes Hydroquinone.

Some examples of skin protectants which may be utilized as the active material in a composition in accordance with the present invention include Allantoin, Aluminium Acetate, Aluminium Hydroxide, Aluminium Sulphate, Calamine, Cocoa Butter, Cod Liver Oil, Colloidal Oatmeal, Dimethicone, Glycerin, Kaolin, Lanolin, Mineral Oil, Petrolatum, Shark Liver Oil, Sodium Bicarbonate, Talc, Witch Hazel, Zinc Acetate, Zinc Carbonate, and Zinc Oxide.

The active material may comprise one or more pesticides, herbicides and/or fungicides including for example Amide Herbicides such as allidochlor N,N-diallyl-2-chloroacetamide; CDEA 2-chloro-N,N-diethylacetamide; etnipromid (RS)-2-[5-(2,4-dichlorophenoxy)-2-nitrophenoxy]-N-ethylpropionamide; anilide herbicides such as cisanilide cis-2,5-dimethylpyrrolidine-1-carboxanilide; flufenacet 4′-fluoro-N-isopropyl-2-[5-(trifluoromethyl)-1,3,4-thiadiazol-2-yloxy]acetanilide; naproanilide (RS)-α-2-naphthoxypropionanilide; arylalanine herbicides such as benzoylprop N-benzoyl-N-(3,4-dichlorophenyl)-DL-alanine; flamprop-M N-benzoyl-N-(3-chloro-4-fluorophenyl)-D-alanine; chloroacetanilide herbicides such as butachlor N-butoxymethyl-2-chloro-2′,6′-diethylacetanilide; metazachlor 2-chloro-N-(pyrazol-1-ylmethyl)acet-2′,6′-xylidide; prynachlor (RS)-2-chloro-N-(1-methylprop-2-ynyl)acetanilide; sulphonanilide herbicides such as cloransulam 3-chloro-2-(5-ethoxy-7-fluoro[1,2,4]triazolo[1,5-c]pyrimidin-2-ylsulphonamido)benzoic acid; metosulam 2′,6′-dichloro-5,7-dimethoxy-3′-methyl[1,2,4]triazolo[1,5-a]pyrimidine-2-sulphonanilide; antibiotic herbicides such as bilanafos 4-[hydroxy(methyl)phosphinoyl]-L-homoalanyl-L-alanyl-L-alanine; benzoic acid herbicides such as chloramben 3-amino-2,5-dichlorobenzoic acid; 2,3,6-TBA 2,3,6-trichlorobenzoic acid; pyrimidinyloxybenzoic acid herbicides such as bispyribac 2,6-bis(4,6-dimethoxypyrimidin-2-yloxy)benzoic acid; pyrimidinylthiobenzoic acid herbicides such as pyrithiobac 2-chloro-6-(4,6-dimethoxypyrimidin-2-ylthio)benzoic acid; phthalic acid herbicides such as chlorthal tetrachloroterephthalic acid; picolinic acid herbicides such as aminopyralid 4-amino-3,6-dichloropyridine-2-carboxylic acid; quinolinecarboxylic acid herbicides such as quinclorac 3,7-dichloroquinoline-8-carboxylic acid; arsenical herbicides such as CMA calcium bis(hydrogen methylarsonate); MAMA ammonium hydrogen methylarsonate; sodium arsenite; benzoylcyclohexanedione herbicides such as mesotrione 2-(4-mesyl-2-nitrobenzoyl)cyclohexane-1,3-dione; benzofuranyl alkylsulphonate herbicides such as benfuresate 2,3-dihydro-3,3-dimethylbenzofuran-5-yl ethanesulphonate; carbamate herbicides such as carboxazole methyl 5-tert-butyl-1,2-oxazol-3-ylcarbamate; fenasulam methyl 4-[2-(4-chloro-o-tolyloxy)acetamido]phenylsulphonylcarbamate; carbanilate herbicides such as BCPC(RS)-sec-butyl 3-chlorocarbanilate; desmedipham ethyl 3-phenylcarbamoyloxyphenylcarbamate; swep methyl 3,4-dichlorocarbanilate; cyclohexene oxime herbicides such as butroxydim (RS)-(EZ)-5-(3-butyryl-2,4,6-trimethylphenyl)-2-(1-ethoxyiminopropyl)-3-hydroxycyclohex-2-en-1-one; tepraloxydim (RS)-(EZ)-2-{1-[(2E)-3-chloroallyloxyimino]propyl}-3-hydroxy-5-perhydropyran-4-ylcyclohex-2-en-1-one; cyclopropylisoxazole herbicides such as isoxachlortole 4-chloro-2-mesylphenyl 5-cyclopropyl-1,2-oxazol-4-yl ketone; dicarboximide herbicides such as flumezin 2-methyl-4-(α,α,α-trifluoro-m-tolyl)-1,2,4-oxadiazinane-3,5-dione; dinitroaniline herbicides such as ethalfluralin N-ethyl-α,α,α-trifluoro-N-(2-methylallyl)-2,6-dinitro-p-toluidine; prodiamine 5-dipropylamino-α,α,α-trifluoro-4,6-dinitro-o-toluidine; dinitrophenol herbicides such as dinoprop 4,6-dinitro-o-cymen-3-ol; etinofen α-ethoxy-4,6-dinitro-o-cresol; diphenyl ether herbicides such as ethoxyfen O-[2-chloro-5-(2-chloro-α,α,α-trifluoro-p-tolyloxy)benzoyl]-L-lactic acid; nitrophenyl ether herbicides such as aclonifen 2-chloro-6-nitro-3-phenoxyaniline; nitrofen 2,4-dichlorophenyl 4-nitrophenyl ether; dithiocarbamate herbicides such as dazomet 3,5-dimethyl-1,3,5-thiadiazinane-2-thione; halogenated aliphatic herbicides such as dalapon 2,2-dichloropropionic acid; chloroacetic acid; imidazolinone herbicides such as imazapyr (RS)-2-(4-isopropyl-4-methyl-5-oxo-2-imidazolin-2-yl)nicotinic acid; inorganic herbicides such as disodium tetraborate decahydrate; sodium azide; nitrile herbicides such as chloroxynil 3,5-dichloro-4-hydroxybenzonitrile; ioxynil 4-hydroxy-3,5-di-iodobenzonitrile; organophosphorus herbicides such as anilofos S-4-chloro-N-isopropylcarbaniloylmethyl O,O-dimethyl phosphorodithioate; glufosinate 4-[hydroxy(methyl)phosphinoyl]-DL-homoalanine; phenoxy herbicides such as clomeprop (RS)-2-(2,4-dichloro-m-tolyloxy)propionanilide; fenteracol 2-(2,4,5-trichlorophenoxy)ethanol; phenoxyacetic herbicides such as MCPA (4-chloro-2-methylphenoxy)acetic acid; phenoxybutyric herbicides such as MCPB 4-(4-chloro-o-tolyloxy)butyric acid; phenoxypropionic herbicides such as fenoprop (RS)-2-(2,4,5-trichlorophenoxy)propionic acid; aryloxyphenoxypropionic herbicides such as isoxapyrifop (RS)-2-[2-[4-(3,5-dichloro-2-pyridyloxy)phenoxy]propionyl]isoxazolidine; phenylenediamine herbicides such as dinitramine N′,N′-diethyl-2,6-dinitro-4-trifluoromethyl-m-phenylenediamine, pyrazolyloxyacetophenone herbicides such as pyrazoxyfen 2-[4-(2,4-dichlorobenzoyl)-1,3-dimethylpyrazol-5-yloxy]acetophenone; pyrazolylphenyl herbicides such as pyraflufen 2-chloro-5-(4-chloro-5-difluoromethoxy-1-methylpyrazol-3-yl)-4-fluorophenoxyacetic acid; pyridazine herbicides such as pyridafol 6-chloro-3-phenylpyridazin-4-ol; pyridazinone herbicides such as chloridazon 5-amino-4-chloro-2-phenylpyridazin-3(2H)-one; oxapyrazon 5-bromo-1,6-dihydro-6-oxo-1-phenylpyridazin-4-yloxamic acid; pyridine herbicides such as fluoroxypyr 4-amino-3,5-dichloro-6-fluoro-2-pyridyloxyacetic acid; thiazopyr methyl 2-difluoromethyl-5-(4,5-dihydro-1,3-thiazol-2-yl)-4-isobutyl-6-trifluoromethylnicotinate; pyrimidinediamine herbicides such as iprymidam 6-chloro-N⁴-isopropylpyrimidine-2,4-diamine; quaternary ammonium herbicides such as diethamquat 1,1′-bis(diethylcarbamoylmethyl)-4,4′-bipyridinium; paraquat 1,1′-dimethyl-4,4-bipyridinium; thiocarbamate herbicides such as cycloate S-ethyl cyclohexyl(ethyl)thiocarbamate; tiocarbazil S-benzyl di-sec-butylthiocarbamate; thiocarbonate herbicides such as EXD O,O-diethyl dithiobis(thioformate); thiourea herbicides such as methiuron 1,1-dimethyl-3-m-tolyl-2-thiourea; triazine herbicides such as triaziflam (RS)—N-[2-(3,5-dimethylphenoxy)-1-methylethyl]-6-(1-fluoro-1-methylethyl)-1,3,5-triazine-2,4-diamine; chlorotriazine herbicides such as cyprazine 6-chloro-N²-cyclopropyl-N⁴-isopropyl-1,3,5-triazine-2,4-diamine; propazine 6-chloro-N²,N⁴-di-isopropyl-1,3,5-triazine-2,4-diamine; methoxytriazine herbicides such as prometon N²,N⁴-di-isopropyl-6-methoxy-1,3,5-triazine-2,4-diamine; methylthiotriazine herbicides such as cyanatryn 2-(4-ethylamino-6-methylthio-1,3,5-triazin-2-ylamino)-2-methylpropionitrile; triazinone herbicides such as hexazinone 3-cyclohexyl-6-dimethylamino-1-methyl-1,3,5-triazine-2,4(1H,3H)-dione; triazole herbicides such as epronaz N-ethyl-N-propyl-3-propylsulphonyl-1H-1,2,4-triazole-1-carboxamide; triazolone herbicides such as carfentrazone (RS)-2-chloro-3-{2-chloro-5-[4-(difluoromethyl)-4,5-dihydro-3-methyl-5-oxo-1H-1,2,4-triazol-1-yl]-4-fluorophenyl}propionic acid; triazolopyrimidine herbicides such as florasulam 2′,6′,8-trifluoro-5-methoxy[1,2,4]triazolo[1,5-c]pyrimidine-2-sulphonanilide; uracil herbicides such as flupropacil isopropyl 2-chloro-5-(1,2,3,6-tetrahydro-3-methyl-2,6-dioxo-4-trifluoromethylpyrimidin-1-yl)benzoate; urea herbicides such as cycluron 3-cyclo-octyl-1,1-dimethylurea; monisouron 1-(5-tert-butyl-1,2-oxazol-3-yl)-3-methylurea; phenylurea herbicides such as chloroxuron 3-[4-(4-chlorophenoxy)phenyl]-1,1-dimethylurea; siduron 1-(2-methylcyclohexyl)-3-phenylurea; pyrimidinylsulphonylurea herbicides such as flazasulphuron 1-(4,6-dimethoxypyrimidin-2-yl)-3-(3-trifluoromethyl-2-pyridylsulphonyl)urea; pyrazosulphuron 5-[(4,6-dimethoxypyrimidin-2-ylcarbamoyl)sulphamoyl]-1-methylpyrazole-4-carboxylic acid; triazinylsulphonylurea herbicides such as thifensulphuron 3-(4-methoxy-6-methyl-1,3,5-triazin-2-ylcarbamoylsulphamoyl)thiophene-2-carboxylic acid; thiadiazolylurea herbicides such as tebuthiuron 1-(5-tert-butyl-1,3,4-thiadiazol-2-yl)-1,3-dimethylurea; and/or unclassified herbicides such as chlorfenac (2,3,6-trichlorophenyl)acetic acid; methazole 2-(3,4-dichlorophenyl)-4-methyl-1,2,4-oxadiazolidine-3,5-dione; tritac (RS)-1-(2,3,6-trichlorobenzyloxy)propan-2-ol.

Flame retardants may also be included as the active material. These include for example Halogen based flame-retardants such as decabromodiphenyloxide, octabromordiphenyl oxide, hexabromocyclododecane, decabromobiphenyl oxide, diphenyoxybenzene, ethylene bis-tetrabromophthalmide, pentabromoethyl benzene, pentabromobenzyl acrylate, tribromophenyl maleic imide, tetrabromobisphenyl A and derivatives thereof, bis-(tribromophenoxy)ethane, bis-(pentabromophenoxy)ethane, polydibomophenylene oxide, tribromophenylallyl ether, bis-dibromopropyl ether, tetrabromophthalic anhydride and derivatives, dibromoneopentyl gycol, dibromoethyl dibromocyclohexane, pentabromodiphenyl oxide, tribromostyrene, pentabromochlorocyclohexane, tetrabromoxylene, hexabromocyclododecane, brominated polystyrene, tetradecabromodiphenoxybenzene, trifluoropropene and PVC. Alternatively they may be Phosphorous based flame-retardants such as (2,3-dibromopropyl)-phosphate, phosphorous, cyclic phosphates, triaryl phosphate, bis-melaminium pentate, pentaerythritol bicyclic phosphate, dimethyl methyl phosphate, phosphine oxide diol, triphenyl phosphate, tris-(2-chloroethyl)phosphate, phosphate esters such as tricreyl, trixylenyl, isodecyl diphenyl, ethylhexyl diphenyl, Phosphate salts of various amines such as ammonium phosphate, trioctyl, tributyl or tris-butoxyethyl phosphate ester. Other flame retardant active materials may include tetraalkyl lead compounds such as tetraethyl lead, iron pentacarbonyl, manganese methyl cyclopentadienyl tricarbonyl, melamine and derivatives such as melamine salts, guanidine, dicayandiamide, silicones such as poldimethylsiloxanes, ammonium sulphamate, alumina trihydrate, and magnesium hydroxide Alumina trihydrate.

Some examples of sunscreen materials which may be utilized as the active material in a composition in accordance with the present invention include Aminobenzoic Acid, Cinoxate, Diethanolamine Methoxycinnamate, Digalloyl Trioleate, Dioxybenzone, Ethyl 4-[bis(Hydroxypropyl)] Aminobenzoate, Glyceryl Aminobenzoate, Homosalate, Lawsone with Dihydroxyacetone, Menthyl Anthranilate, Octocrylene, Octyl Methoxycinnamate, Octyl Salicylate, Oxybenzone, Padimate O, Phenylbenzimidazole Sulphonic Acid, Red Petrolatum, Sulisobenzone, Titanium Dioxide, and Trolamine Salicylate.

Some examples of UV light absorbing materials which may be utilized as the active material in a composition in accordance with the present invention include Acetaminosalol, Allatoin PABA, Benzalphthalide, Benzophenone, Benzophenone 1-12, 3-Benzylidene Camphor, Benzylidenecamphor Hydrolyzed Collagen Sulphonamide, Benzylidene Camphor Sulphonic Acid, Benzyl Salicylate, Bornelone, Bumetriozole, Butyl Methoxydibenzoylmethane, Butyl PABA, Ceria/Silica, Ceria/Silica Talc, Cinoxate, DEA-Methoxycinnamate, Dibenzoxazol Naphthalene, Di-t-Butyl Hydroxybenzylidene Camphor, Digalloyl Trioleate, Diisopropyl Methyl Cinnamate, Dimethyl PABA Ethyl Cetearyldimonium Tosylate, Dioctyl Butamido Triazone, Diphenyl Carbomethoxy Acetoxy Naphthopyran, Disodium Bisethylphenyl Triaminotriazine Stilbenedisulphonate, Disodium Distyrylbiphenyl Triaminotriazine Stilbenedisulphonate, Disodium Distyrylbiphenyl Disulphonate, Drometrizole, Drometrizole Trisiloxane, Ethyl Dihydroxypropyl PABA, Ethyl Diisopropylcinnamate, Ethyl Methoxycinnamate, Ethyl PABA, Ethyl Urocanate, Etrocrylene Ferulic Acid, Glyceryl Octanoate Dimethoxycinnamate, Glyceryl PABA, Glycol Salicylate, Homosalate, Isoamyl p-Methoxycinnamate, Isopropylbenzyl Salicylate, Isopropyl Dibenzolylmethane, Isopropyl Methoxycinnamate, Menthyl Anthranilate, Menthyl Salicylate, 4-Methylbenzylidene, Camphor, Octocrylene, Octrizole, Octyl Dimethyl PABA, Octyl Methoxycinnamate, Octyl Salicylate, Octyl Triazone, PABA, PEG-25 PABA, Pentyl Dimethyl PABA, Phenylbenzimidazole Sulphonic Acid, Polyacrylamidomethyl Benzylidene Camphor, Potassium Methoxycinnamate, Potassium Phenylbenzimidazole Sulphonate, Red Petrolatum, Sodium Phenylbenzimidazole Sulphonate, Sodium Urocanate, TEA-Phenylbenzimidazole Sulphonate, TEA-Salicylate, Terephthalylidene Dicamphor Sulphonic Acid, Titanium Dioxide, TriPABA Panthenol, Urocanic Acid, and VA/Crotonates/Methacryloxybenzophenone-1 Copolymer.

Catalysts which may be utilized as the active material in a composition in accordance with the present invention may include particles that contain metals such as Pt, Rh, Ir, Ag, Au, Pd, Cu, Ru, Ni, Mg, Co or other catalytically active metals. Mixtures of metals such as Pt—Rh, Rh—Ag, V—Ti or other well known mixtures may also be used. The metal may exist in its elemental state, as a fine powder, or as a complex such as a metallocene, chloride, carbonyl, nitrate or other well known forms. Pure oxides such as CeOₓ, P₂O₅, TiO₂, ZrO₂, or mixed metal oxides such as aluminosilicates or perovskites can also give catalytic activity. Alternatively, non-metallic catalysts may be used. Examples of such non-metallic catalysts include sulphuric acid, acetic acid, sodium hydroxide or phosphoric acids. In the case of a catalyst or the like, the coating derived from the coating forming material may be a simple polymer designed to disperse and entrap active material and in the case where the active material is (e.g. a catalyst), or it may act to promote the activity of the catalyst material through well-known catalyst support interactions. Examples of such interactions are those found in Rh supported on ceria, Ni supported on alumina, Pt supported on Ce_{0.6}Zr_{0.4}O₂, Cr supported on titania and/or titanium or Pt—Pd supported on magnesium oxide. The active material may comprise oleophobic materials such as particulate polytetrafluoroethylene (PTFE).

Dispersing a conducting active material in a polymer matrix may give rise to conductive coatings. The conductive material may comprise any conductive particle, typically of silver but alternative conductive particles might be used including gold, nickel, copper, assorted metal oxides and/or carbon including carbon nanotubes; or metallised glass or ceramic beads. Conductivity enhancing materials, such as those described in U.S. Pat. No. 6,599,446 may also be added.

It is to be understood that the coating forming material in accordance with the present invention is a precursor material which is reactive within the atmospheric pressure plasma or as part of a PE-CVD process and can be used to make any appropriate coating, including, for example, a material which can be used to grow a film or to chemically modify an existing surface. The present invention may be used to form many different types of coatings. The type of coating which is formed on a substrate is determined by the coating-forming material(s) used, and the present method may be used to (co)polymerise coating-forming monomer material(s) onto a substrate surface.

The coating-forming material may be organic or inorganic, solid, liquid or gaseous, or mixtures thereof. Suitable organic coating-forming materials include carboxylates, methacrylates, acrylates, styrenes, methacrylonitriles, alkenes and dienes, for example methyl methacrylate, ethyl methacrylate, propyl methacrylate, butyl methacrylate, and other alkyl methacrylates, and the corresponding acrylates, including organofunctional methacrylates and acrylates, including poly(ethyleneglycol) acrylates and methacrylates, glycidyl methacrylate, trimethoxysilyl propyl methacrylate, allyl methacrylate, hydroxyethyl methacrylate, hydroxypropyl methacrylate, dialkylaminoalkyl methacrylates, and fluoroalkyl (meth)acrylates, methacrylic acid, acrylic acid, fumaric acid and esters, itaconic acid (and esters), maleic an hydride, styrene, α-methylstyrene, halogenated alkenes, for example, vinyl halides, such as vinyl chlorides and vinyl fluorides, and fluorinated alkenes, for example perfluoroalkenes, acrylonitrile, methacrylonitrile, ethylene, propylene, allyl amine, vinylidene halides, butadienes, acrylamide, such as N-isopropylacrylamide, methacrylamide, epoxy compounds, for example glycidoxypropyltrimethoxysilane, glycidol, styrene oxide, butadiene monoxide, ethyleneglycol diglycidylether, glycidyl methacrylate, bisphenol A diglycidylether (and its oligomers), vinylcyclohexene oxide, conducting polymers such as pyrrole and thiophene and their derivatives, and phosphorus-containing compounds, for example dimethylallylphosphonate. The coating forming material may also comprise acryl-functional organosiloxanes and/or silanes.

Suitable inorganic coating-forming materials include metals and metal oxides, including colloidal metals. Organometallic compounds may also be suitable coating-forming materials, including metal alkoxides such as titanates, tin alkoxides, zirconates and alkoxides of germanium and erbium. However, the present inventors have found that the present invention has particular utility in providing substrates with siloxane-based coatings using coating-forming compositions comprising silicon-containing materials. Suitable silicon-containing materials for use in the method of the present invention include silanes (for example, silane, alkylsilanes, alkylhalosilanes, alkoxysilanes) and linear (for example, polydimethylsiloxane) and cyclic siloxanes (for example, octamethylcyclotetrasiloxane), including organo-functional linear and cyclic siloxanes (for example, Si—H containing, halo-functional, and haloalkyl-functional linear and cyclic siloxanes, e.g. tetramethylcyclotetrasiloxane and tri(nonofluorobutyl)trimethylcyclotrisiloxane). A mixture of different silicon-containing materials may be used, for example to tailor the physical properties of the substrate coating for a specified need (e.g. thermal properties, optical properties, such as refractive index, and viscoelastic properties).

The substrate to be coated may comprise any material other than a wipe, cloth or sponge for household care or depilatory care or a water soluble household cleaning unit dose product. For example plastics for example thermoplastics such as polyolefins e.g. polyethylene, and polypropylene, polycarbonates, polyurethanes, polyvinylchloride, polyesters (for example polyalkylene terephthalates, particularly polyethylene terephthalate), polymethacrylates (for example polymethylmethacrylate and polymers of hydroxyethylmethacrylate), polyepoxides, polysulphones, polyphenylenes, polyetherketones, polyimides, polyamides, polystyrenes, polyfluoroalkanes such as PTFE, poly(siloxanes) such as poly(dimethylsiloxanes) including silicone pressure sensitive adhesives, silicone gels and silicone elastomers, phenolic, epoxy and melamine-formaldehyde resins, and blends and copolymers thereof. Preferred organic polymeric materials are polyolefins, in particular polyethylene and polypropylene. Other substrates include metallic thin films made from e.g. aluminium, steel, stainless steel and copper or the like.

The substrate may be in the form of a flat web (film, paper, fabric, non-woven, metallic foil, powder and moulded or engineered components or extruded forms such as tubes and ribbons. Powders may include, for example any suitable material, for example metals, metal oxides, silica and silicates, carbon, organic powdered substrates, mineral fillers such as for example carbon black, clays, CaCO₃, talc, silica, mica conductive fillers, TiO₂ nanoparticles, metal oxides such as TiO2, ZrO₂, Fe₂O₃ Al₂O₃SiO₂, B₂O₃, Li₂O, Na₂O, PbO, ZnO, or, CaO, Pb₃O₄ and CuO and mixed oxides, graphite, phosphorus particles, pigments and the like; metalloid oxides, mixed oxide, organometallic oxides, organometalloid oxides, organomixed oxide resins and/or an organic resin, sodium carbonate potassium nitrate, silicon metal particles, silicone rubber crumb, siloxane resins of the type commonly referred to as MQ or T-resins, siloxane waxes and/or organic rubber crumb such as EPDM and Polypropylene.

The substrate may be in the form of synthetic and/or, natural fibres, woven or non-woven fibres, powder, siloxane, fabrics, woven or non-woven fibres, natural fibres such as alginates, cellulosics, chitosan, collagen, biosynthetic, human-based tissue based dressings, synthetic fibres cellulosic material and powder or a blend of an organic polymeric material and a organosilicon-containing additive which is miscible or substantially non-miscible with the organic polymeric material as described in the applicants co-pending patent application WO 01/40359 with the exclusion of Wipes, Cloths and Sponges for hard surface cleaning

Applications:

### Textiles & non-wovens, powders, medical materials & wound care, cosmetics, household care goods excluding Wipes, Cloths and Sponges for hard surface cleaning.

The textiles may comprise Clothing (sports, leisure, medical and/or military); Non-woven materials e.g. medical drape & clothing filter means for liquids and separations of for example water, food and beverages applications, or medical applications.); air filtration means for air conditioning and ventilation, automotive, clean room, sterile room (industrial & medical); and Cosmetic wipes.

Powders: —such as for example: Fragrances, flavours, separations (for water, food beverage and medical applications) and formulation excipients; Sensors such as for example Chemical and Bio-sensors;

Medical applications such as for:

Wound care including bandages, plasters, casts, wound dressings, adhesive tapes, gels, pastes, pads, gauzes, swabs, tissue engineered products (e.g. biosynthetic, human-based tissue based dressings) drug delivery formulations (including transdermal patches, topical patches, medicated bandages, implantable pump, implants and inserts) and biomaterials, medical devices (including stents, shunts, ostomy devices, blood collection pouches), surgical drapes, catheters and tubings, contact lenses, surgical implants, prosthesis; oral care devices including floss, bristles, toothpick, adhesive strips (e.g. whitening), swabs and tablets and sticks (e.g. chewing gum).

Construction applications such as Floor and wall coverings.

Any suitable means for generating the plasma may be utilised including, for example, corona and diffuse dielectric barrier discharge. Any conventional means for generating an atmospheric pressure plasma diffuse dielectric barrier discharge may be used in the present invention, for example atmospheric pressure plasma jet, atmospheric pressure microwave glow discharge and atmospheric pressure glow discharge.

Preferably the current invention utilises equipment similar to that described in WO 02/28548, wherein liquid based polymer precursors are introduced as an aerosol into an atmospheric plasma discharge or the excited species therefrom. However, the reactive polymer precursors are also mixed with active materials, which are non-reactive within the atmospheric diffuse dielectric barrier discharge such as glow discharge. The active materials are chosen as they substantially avoid reactions in the plasma environment. One advantage of this method compared to WO 02/28548 is that active materials, which substantially do not undergo chemical bond forming reactions within a plasma environment, may be incorporated into the plasma deposited coating without degradation of the active properties. Thus an active coating can be readily prepared by atmospheric PE-CVD as well as when using liquid precursors.

An additional advantage of this method is that diffusion of the active from the coating may be controlled by the properties of the plasma coating. Diffusion is hindered by increased cross-linking, which may give rise to controlled release properties. Diffusion may also be hindered to the point where active is not released from the coating, either by increasing the cross-link density or over coating with a barrier coating. An advantage of the present invention over the prior art is that both liquid and solid atomised coating-forming materials may be used to form substrate coatings, due to the method of the present invention taking place under conditions of atmospheric pressure. Furthermore the coating-forming materials can be introduced into the plasma discharge or resulting stream in the absence of a carrier gas, i.e. they can be introduced directly by, for example, direct injection, whereby the coating forming materials are injected directly into the plasma.

For typical diffuse dielectric barrier discharge plasma generating apparatus, the homogeneous plasma is generated between a pair of electrodes within a gap of from 3 to 50 mm, for example 5 to 25 mm. Thus, the present invention has particular utility for coating films, fibres and powders. The generation of steady-state homogeneous diffuse dielectric barrier discharge such as glow discharge plasma at atmospheric pressure is preferably obtained between adjacent electrodes that may be spaced up to 5 cm apart, dependent on the process gas used. The electrodes being radio frequency energised with a root mean square (rms) potential of 1 to 100 kV, preferably between 1 and 30 kV at 1 to 100 kHz, preferably at 15 to 50 kHz. The voltage used to form the plasma will typically be between 1 and 30 kVolts, most preferably between 2.5 and 10 kV however the actual value will depend on the chemistry/gas choice and plasma region size between the electrodes.

Any suitable electrode systems may be utilised. Each electrode may comprise a metal plate or metal gauze or the like retained in a dielectric material or may, for example, be of the type described the applicants co-pending application WO 02/35576 wherein there are provided electrode units containing an electrode and an adjacent a dielectric plate and a cooling liquid distribution system for directing a cooling conductive liquid onto the exterior of the electrode to cover a planar face of the electrode. Each electrode unit comprises a watertight box having one side in the form of a dielectric plate to which a metal plate or gauze electrode is attached on the inside of the box. There is also a liquid inlet and a liquid outlet fitted to a liquid distribution system comprising a cooler and a recirculation pump and/or a sparge pipe incorporating spray nozzles. The cooling liquid covers the face of the electrode remote from the dielectric plate. The cooling conductive liquid is preferably water and may contain conductivity controlling compounds such as metal salts or soluble organic additives. Ideally, the electrode is a metal plate or mesh electrode in contact with the dielectric plate. The dielectric plate extends beyond the perimeter of the electrode and the cooling liquid is also directed across the dielectric plate to cover at least that portion of dielectric bordering the periphery of the electrode. Preferably, all the dielectric plate is covered with cooling liquid. The water acts to electrically passivate any boundaries, singularities or non-uniformity in the metal electrodes such as edges, corners or mesh ends where the wire mesh electrodes are used.

In another alternative system each electrode may be of the type described the applicants co-pending application No WO 2004/068916 which was published after the priority date of the present application. In WO 2004/068916 each electrode comprises a housing having an inner and outer wall, wherein at least the inner wall is formed from a dielectric material, and which housing contains an at least substantially non-metallic electrically conductive material in direct contact with the inner wall instead of the “traditional” metal plate or mesh. Electrodes of this type are preferred because the inventors have identified that by using electrodes in accordance with the present invention to generate a diffuse dielectric barrier discharge, the resulting homogeneous plasma can be generated with reduced inhomogeneities when compared to systems utilizing metal plate electrodes. A metal plate is never fixed directly to the inner wall of an electrode in the present invention and preferably, the non-metallic electrically conductive material is in direct contact with the inner wall of the electrode.

Dielectric materials referred to in the present application may be of suitable type examples include but are not restricted to polycarbonate, polyethylene, glass, glass laminates, epoxy filled glass laminates and the like. Preferably, the dielectric has sufficient strength in order to prevent any bowing or disfigurement of the dielectric by the conductive material in the electrode. Preferably, the dielectric used is machinable and is provided at a thickness of up to 50 mm in thickness, more preferably up to 40 mm thickness and most preferably 15 to 30 mm thickness. In instances where the selected dielectric is not sufficiently transparent, a glass or the like window may be utilized to enable diagnostic viewing of the generated plasma.

The electrodes may be spaced apart by means of a spacer or the like, which is preferably also made from a dielectric material which thereby effects an increase in the overall dielectric strength of the system by eliminating any potential for discharge between the edges of the conductive liquid.

The substantially non-metallic electrically conductive material may be a liquid such as a polar solvent for example water, alcohol and/or glycols or aqueous salt solutions and mixtures thereof, but is preferably an aqueous salt solution. When water is used alone, it preferably comprises tap water or mineral water. Preferably, the water contains up to a maximum of about 25% by weight of a water-soluble salt such as an alkali metal salt, for example sodium or potassium chloride or alkaline earth metal salts. This is because the conductive material present in such an electrode has substantially perfect conformity and thereby a perfectly homogeneous surface potential at the dielectric surface.

Alternatively, the substantially non-metallic electrically conductive material may be in the form of one or more conductive polymer compositions, which may typically be supplied in the form of pastes. Such pastes are currently used in the electronics industry for the adhesion and thermal management of electronic components, such as microprocessor chip sets. These pastes typically have sufficient mobility to flow and conform to surface irregularities.

Suitable polymers for the conductive polymer compositions in accordance with the present invention may include silicones, polyoxypolyeolefin elastomers, a hot melt based on a wax such as a, silicone wax, resin/polymer blends, silicone polyamide copolymers or other silicone-organic copolymers or the like or epoxy, polyimide, acrylate, urethane or isocyanate based polymers. The polymers will typically contain conductive particles, typically of silver but alternative conductive particles might be used including gold, nickel, copper, assorted metal oxides and/or carbon including carbon nanotubes; or metallised glass or ceramic beads. Specific examples polymers which might be used include the conductive polymer described in EP 240648 or silver filled organopolysiloxane based compositions such as Dow Corning® DA 6523, Dow Corning® DA 6524, Dow Corning® DA 6526 BD, and Dow Corning® DA 6533 sold by Dow Corning Corporation or silver filled epoxy based polymers such as Ablebond® 8175 from (Ablestik Electronic Materials & Adhesives) Epo-Tek® H20E-PFC or Epo-Tek® E30 (Epoxy Technology Inc).

One example of the type of assembly which might be used on an industrial scale with electrodes in accordance with the present invention is wherein there is provided an atmospheric pressure plasma assembly comprising a first and second pair of parallel spaced-apart electrodes in accordance with the present invention, the spacing between inner plates of each pair of electrodes forming a first and second plasma zone wherein the assembly further comprises a means of transporting a substrate successively through said first and second plasma zones and an atomiser adapted to introduce an atomised liquid or solid coating making material into one of said first or second plasma zones. The basic concept for such equipment is described in the applicant's co-pending application WO 03/086031 which is incorporated herein by reference.

In a preferred embodiment, the electrodes are vertically arrayed.

As has been previously described herein one major advantage of the use of liquids for conducting materials is that each pair of electrodes can have a different amount of liquid present in each electrode resulting in a different sized plasma zone and therefore, path length and as such potentially a different reaction time for a substrate when it passes between the different pairs of electrodes. This might mean that the period of reaction time for a cleaning process in the first plasma zone may be different from path length and/or reaction time in the second plasma zone when a coating is being applied onto the substrate and the only action involved in varying these is the introduction of differing amounts of conducting liquid into the differing pairs of electrodes. Preferably, the same amount of liquid is used in each electrode of an electrode pair where both electrodes are as hereinbefore described.

An alternative means of generating the required plasma for the present invention is by means of an atmospheric pressure plasma jet (APPJ). An APPJ is a non-thermal equilibrium plasma. This consists of a one electrode (a needle form) or two electrode form i.e. concentric electrodes over which or between which respectively a process gas e.g. helium is supplied. By applying a sufficiently high power and potential a plasma is ignited and the ionised/excited gas generated by the plasma is directed through a nozzle and onto a substrate a short distance from the nozzle tip. The plasma produced by an APPJ system is directed from the space between the electrodes (the plasma zone) as a flame-like phenomenon and can be used to treat remote objects. A number of alternative designs for plasma jet systems suitable for use in the present invention when supplied with a suitable atomiser are described below with the assistance of the Figures.

The coating-forming material may be atomised using any conventional means, for example an ultrasonic nozzle. The material to be atomised is preferably in the form of a liquid, or a liquid/solid slurry. The atomiser preferably produces a coating-forming material drop size of from 10 to 100 μm, more preferably from 10 to 50 μm. Preferred atomisers include, for example, ultrasonic nozzles, pneumatic or vibratory atomisers in which energy is imparted at high frequency to the liquid. The vibratory atomisers may use an electromagnetic or piezoelectric transducer for transmitting high frequency oscillations to the liquid stream discharged through an orifice. These tend to create substantially uniform droplets whose size is a function of the frequency of oscillation. Suitable ultrasonic nozzles which may be used include ultrasonic nozzles from Sono-Tek Corporation, Milton, N.Y., USA or Lechler GmbH of Metzingen Germany. Other suitable atomisers which may be utilised include gas atomising nozzles, pneumatic atomisers, pressure atomisers and the like. The apparatus of the present invention may include a plurality of atomisers, which may be of particular utility, for example, where the apparatus is to be used to form a copolymer coating on a substrate from two different coating-forming materials, where the monomers are immiscible or are in different phases, e.g. the first is a solid and the second is gaseous or liquid.

Preferably where suitable the active material is introduced into the system using the same atomiser(s) with which the coating forming material is introduced. However, the active material may be introduced into the system via a second or second series of atomisers or other introducing means, preferably simultaneously with the introduction of the coating-forming material. Any suitable alternative introducing means may be utilised such as for example compressed gas and/or gravity feed powder feeders. Where a carrier gas is used any suitable carrier gas may be utilised although helium is preferred.

The process gas used to generate a plasma suitable for use in the present invention may be any suitable gas but is preferably an inert gas or inert gas based mixture such as, for example helium, argon, nitrogen and mixtures comprising at least one of the preceding gases, such as, a mixture of helium and argon or an argon based mixture additionally containing ketones and/or related compounds. These process gases may be utilized alone or in combination with potentially reactive gases such as, for example, ammonia, O₂, H₂O, NO₂, air or hydrogen. Most preferably, the process gas will be Helium alone or in combination with an oxidizing or reducing gas. The selection of gas depends upon the plasma processes to be undertaken. When an oxidizing or reducing process gas is required, it will preferably be utilized in a mixture comprising 90-99% noble gas and 1 to 10% of oxidizing or reducing gas.

Under oxidising conditions the present method may be used to form an oxygen containing coating on the substrate. For example, silica-based coatings can be formed on the substrate surface from atomised silicon-containing coating-forming materials. Under reducing conditions, the present method may be used to form oxygen free coatings, for example, silicon carbide based coatings may be formed from atomised silicon containing coating forming materials.

In a nitrogen containing atmosphere nitrogen can bind to the substrate surface, and in an atmosphere containing both nitrogen and oxygen, nitrates can bind to and/or form on the substrate surface. Such gases may also be used to pre-treat the substrate surface prior to exposure to a coating forming substance. For example, oxygen containing plasma treatment of the substrate may provide improved adhesion between the substrate and the applied coating with oxygen containing plasma being generated by introducing oxygen containing materials, such as oxygen gas or water, to the plasma.

In one embodiment the coated substrate of the present invention may be coated with a plurality of layers of differing composition. These may be applied by passing the substrate relative to a plurality of plasma regions or by repeatedly passing the substrate or partially coated substrate repeatedly relative to the plasma regions. Where appropriate the substrate or the plasma system may move relative to the other. Any suitable number of cycles or plasma zones may be utilised in order to achieve the appropriate multi-coated substrates. The substrate may pass through a plasma zone, adjacent a plasma zone through or remote from the excited gas stream or even remote thereof such that the substrate may be maintained outside the region affected by the plasma and/or excited gas stream.

For example, the substrate utilised in accordance to the present invention may be subjected to a plurality of plasma regions, each of which can function differently e.g. a first plasma region might be utilised as a means of oxidising the substrate surface (in for example, an oxygen/Helium process gas) or as a means of applying a first coating and the application of an active material containing coating may take place in a second plasma region which may or may not be post-treated With for example the addition of a further protective coating. The method of the present invention is therefore suitable to any number of required coating layers as required for the end use concerned.

In a still further embodiment where a substrate is to be coated, rather than having a multiple series of plasma assemblies, a single plasma assembly may be utilised with a means for varying the materials passing through the plasma zone formed between the electrodes. For example, initially the only substance passing through the plasma zone might be the process gas such as helium which is excited by the application of the potential between the electrodes to form a plasma zone. The resulting helium plasma may be utilised to clean and/or activate the substrate that is passed through or relative to the plasma zone. Then one or more coating forming precursor material(s) and the active material may be introduced and the one or more coating forming precursor material(s) are excited by passing through the plasma zone and treating the substrate. The substrate may be moved through or relative to the plasma zone on a plurality of occasions to effect a multiple layering and where appropriate the composition of the coating forming precursor material(s) may be varied by replacing, adding or stopping the introduction of one or more for example introducing one or more coating forming precursor material(s) and/or active materials.

Any suitable non-thermal equilibrium plasma equipment may be used to undertake the method of the present invention, however atmospheric pressure diffuse dielectric barrier discharge generating equipment or low pressure glow discharge, which may be operated in either continuous mode or pulse mode are preferred.

The plasma equipment may also be in the form of an APPJ as described in WO 03/085693. Where the substrate is placed downstream and remote from the plasma source.

Any conventional means for generating an atmospheric pressure diffuse dielectric barrier discharge such as a glow discharge may be used in the method of the present invention, for example atmospheric pressure plasma jet, atmospheric pressure microwave glow discharge and atmospheric pressure glow discharge. Typically, such means will employ helium, argon or nitrogen or mixtures containing at least one of the latter as the process gas, although a helium process gas is preferred and a high frequency (e.g. >1 kHz) power supply to generate a homogeneous diffuse dielectric barrier discharge.

In the case of (low pressure (glow discharge plasma) the liquid precursor and the active material is preferably either retained in a container or is introduced into the reactor in the form of an atomised liquid spray as described above. The low pressure plasma may be performed with liquid precursor and/or active material heating and/or pulsing of the plasma discharge, but is preferably carried out without the need for additional heating. If heating is required, the method in accordance with the present invention using low pressure plasma techniques may be cyclic, i.e. the liquid precursor is plasma treated with no heating, followed by heating with no plasma treatment, etc., or may be simultaneous, i.e. liquid precursor heating and plasma treatment occurring together. The plasma may be generated by way of the electromagnetic radiations from any suitable source, such as radio frequency, microwave or direct current (DC). A radio frequency (RF) range between 8 and 16 MHz is suitable with an RF of 13.56 MHz preferred. In the case of low pressure glow discharge any suitable reaction chamber may be utilized. The power of the electrode system may be between 1 and 100 W, but preferably is in the region of from 5 to 50 W for continuous low pressure plasma techniques. The chamber pressure may be reduced to any suitable pressure for example from 0.1 to 0.001 mbar but preferably is between 0.05 and 0.01 mbar.

A particularly preferred pulsed plasma treatment process involves pulsing the plasma discharge at room temperature. The plasma discharge is pulsed to have a particular “on” time and “off” time, such that a very low average power is applied, for example a power of less than 10 W and preferably less than 1 W. The on-time is typically from 10 to 10000 μs, preferably 10 to 1000 μs, and the off-time typically from 1000 to 10000 μs, preferably from 1000 to 5000 μs. Atomised liquid precursors and the active material(s) may be introduced into the vacuum with no additional gases, i.e. by direct injection, however additional process gases such as helium or argon may also be utilized as carriers where deemed necessary.

In the case of the low pressure plasma options the process gas for forming the plasma may be as described for the atmospheric pressure system but may alternatively not comprise noble gases such as helium and/or argon and may therefore purely be oxygen, air or an alternative oxidising gas.

The present invention will now be illustrated in detail with reference to the accompanying figures drawing and the Examples, in which: —

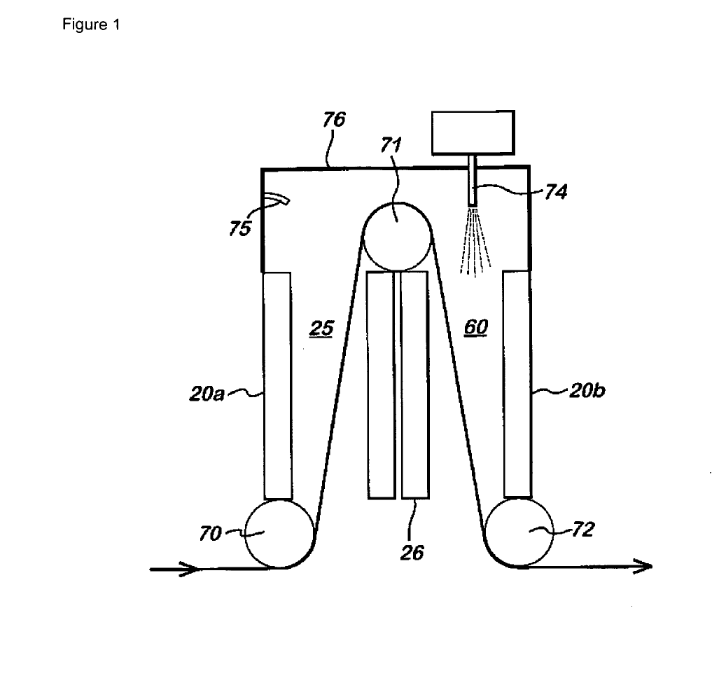

FIG. 1 is a general view of a plasma generating unit as used in the Examples herein below

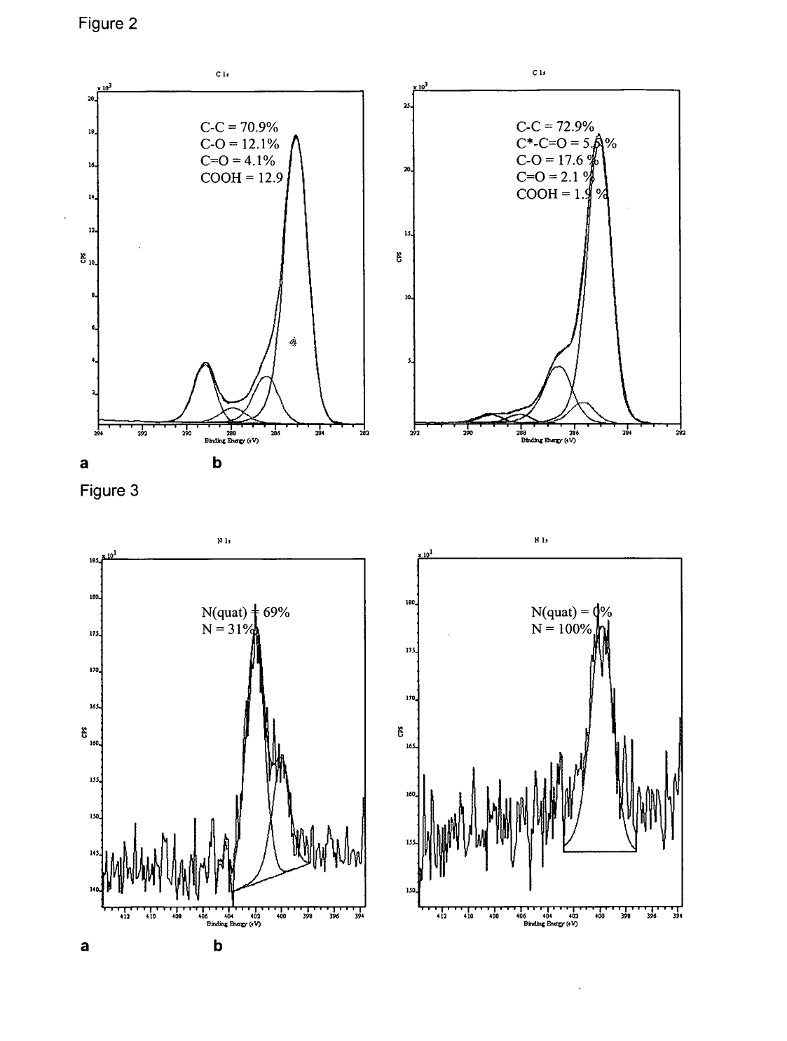

FIG. 2 is a High resolution carbon (C 1s) spectra for cetalkonium chloride deposited in a) acrylic acid, b) PEG methacrylate

FIG. 3 is a High resolution nitrogen (N 1s) spectrum for Cetylalkonium chloride deposited in acrylic acid a) before washing, b) after washing in NaOH

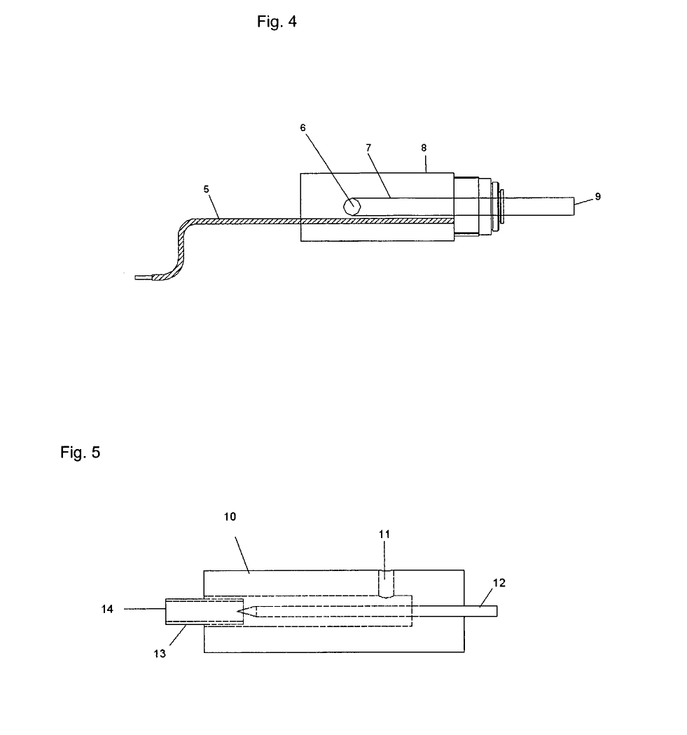

FIGS. 4 to 7 are alternative designs for plasma jet equipment which may be utilised in the present invention

### EXPERIMENTAL

### Sample Preparation

Solid salts of cetalkonium chloride, benzalkonium chloride and cetyl pyridinium chloride (active materials) were dissolved in acrylic acid or polyethylene glycol (PEG) methacrylates (coating-forming materials as described in Table 1

TABLE 1
Composition of quaternary salt solutions

| Solid | Weight (g) | Solvent | Weight (g) |
|---|---|---|---|
| Cetalkonium chloride | 0.38 | Acrylic acid | 16.1 |
| Benzalkonium chloride | 0.40 | Acrylic acid | 16.0 |
| Cetylpyridinium chloride | 0.29 | Acrylic acid | 12.0 |
| Cetalkonium chloride | 0.48 | PEG methacrylate | 16.0 |
| | | PEG dimethacrylate | 16.3 |
| Benzalkonium chloride | 0.25 | PEG methacrylate | 9.6 |
| | | PEG dimethacrylate | 6.5 |
| Cetylpyridinium chloride | 0.25 | PEG methacrylate | 8.0 |
| | | PEG dimethacrylate | 7.2 |
| | | Acrylic acid | 4.5 |

### The chemical structures for the salts are given below

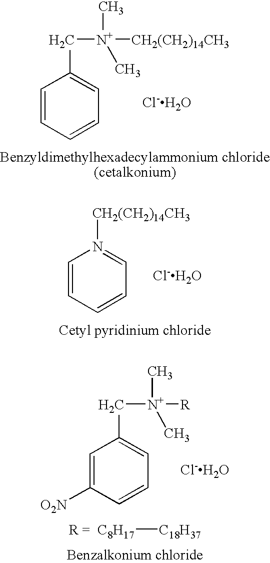

The precursor solutions comprising the coating-forming material and the active materials were then deposited onto polypropylene and polyester fabric substrates using a diffuse dielectric barrier discharge assembly of the type shown in FIG. 1.

Referring now to FIG. 1, the flexible polypropylene and polyester fabric substrate was transported through the plasma assembly by means of guide rollers 70, 71 and 72. A helium process gas inlet 75, an assembly lid 76 and an ultrasonic nozzle 74 for introducing atomised precursor solutions into plasma region 60 are provided. Plasma power used in both plasma regions varied between 0.4 and 1.0 kW.

In use a 100 mm wide web of flexible substrate was transported through the plasma assembly at a speed of speed was varied between 1 and 4 mmin⁻¹. The substrate was initially directed to and over guide roller 70 through plasma region 25 between electrodes 20a and 26. The plasma generated between electrodes 20a and 26 in plasma region 25 was utilised as a cleaning helium plasma, i.e. no reactive material is directed into plasma region 25. Helium was introduced into the system by way of inlet 75. Lid 76 is placed over the top of the system to prevent the escape of helium, as it is lighter than air. Upon leaving plasma region 25 the plasma cleaned substrate passes over guide 71 and is directed down through plasma region 60, between electrodes 26 and 20b and over roller 72. Plasma region 60 however is utilised to coat the substrate with plasma treated precursor solution introduced in a liquid form through ultrasonic nozzle introduced at a rate of between 25-50 μLmin⁻¹.

The precursor solution is itself plasma treated when passing through plasma region 60 generating a coating for the substrate in which the active materials are retained. The coated substrate then passes through plasma region 60 and is coated and then is transported over roller 72 and is collected or further treated with additional plasma treatments. Rollers 70 and 72 may be reels as opposed to rollers. Having passed through is adapted to guide the substrate into plasma region 25 and on to roller 71.

Table 2 describes the coating conditions used to prepare the samples, along with the corresponding analytical reference.

TABLE 2
Coating conditions

| Coating Conditions | Example Reference |
|---|---|
| Cetalkonium chloride/Acrylic acid | 1a |
| 0.4 kW, 25 μlmin⁻¹ | |
| Cetalkonium chloride/Acrylic acid | 1b |
| 1.0 kW, 25 μlmin⁻¹ | |
| Cetalkonium chloride/Acrylic acid | 1c |
| 0.4 kW, 50 μlmin⁻¹ | |
| Cetalkonium chloride/Acrylic acid | 1d |
| 0.4 kW, 50 μlmin⁻¹ | |
| Cetyl pyridinium chloride/Acrylic | 1e |
| acid 1.0 kW, 25 μlmin⁻¹ | |
| Cetyl pyridinium chloride/Acrylic | 1f |
| acid 0.4 kW, 25 μlmin⁻¹ | |
| Benzalkonium chloride/Acrylic acid | 1g |
| 1.0 kW, 25 μlmin⁻¹ | |
| Benzalkonium chloride/Acrylic acid | 1h |
| 0.4 kW, 25 μlmin⁻¹ | |
| Cetalkonium chloride/PEG acrylate | 1i |
| 1.0 kW, 25 μlmin⁻¹ | |
| Cetalkonium chloride/Acrylic acid | 1j |
| 0.4 kW, 25 μlmin⁻¹ | |

Samples were then washed by immersing a piece of coated film in the one of the following solutions for 10 minutes at ambient temperature:

| | |
|---|---|
| pH 2 | 0.01M HCl |
| pH 7 | HPLC grade water |
| pH 12 | 0.01M NaOH |

All samples were then submitted for X-ray Photoelectron Spectroscopy (XPS) analysis which involves the irradiation of a sample with soft X-rays, and the energy analysis of photoemitted electrons that are generated close to the sample surface. XPS has the ability to detect all elements (with the exception of hydrogen and helium) in a quantitative manner from an analysis depth of less than 10 nm. In addition to elemental information, XPS is also used to probe the chemical state of elements through the concept of binding energy shift. All values quoted in this report are an average of at least three different analyses.

| | |
|---|---|
| Instrument: | Kratos Analytical Axis Ultra |
| Sampling: | Monochromated Al K X-rays |
| Spectra Acquired: | Survey, Na 1s, O 1s, N 1s, C 1s |

### Anti-Microbial Testing

Anti-microbial testing was carried out using a modified version of ISO846 norm (“Plastics—Evaluation of the action of microorganisms”). Fabric and plastic samples were exposed to a mixed suspension of fungal spores in the presence of a complete medium, for a specified period of time (4 weeks) and in specified conditions of temperature (28° C.±1° C.) and humidity. The dishes were examined every 2 days in order to ensure spore viability. The final and official examination is performed after 4 incubation weeks. The broad spectrum efficiency of a material is determined by the “growth rating” scale from 0 to 5, in Table 3. This scale measured the extent to which visible fungal growth is inhibited on the material sample being tested.

TABLE 3
Evaluation criteria for microbial tests

| Intensity of growth | Evaluation |
|---|---|
| 0 | No growth apparent under the stereomicroscope. |
| 1 | No growth visible to the naked eye, but clearly |
| | visible under the stereomicroscope. |
| 2 | Growth visible to the naked eye, covering up to 25% |
| | of the test surface. |
| 3 | Growth visible to the naked eye, covering up to 50% |
| | of the test surface. |
| 4 | Considerable growth, covering more than 50% of |
| | the test surface. |
| 5 | Heavy growth, covering the entire test surface |
| | (=zero protection). |

The examples above demonstrate the incorporation of a quaternary ammonium surfactant (anti-microbial) into a polyethylene glycol PEG coating what substrate. The coating is resistant to water, acid and base washing.

All samples coated with the quaternary salt solutions gave rise to clear, hydrophilic coatings with good substrate coverage. XPS analysis was used to probe the surface chemistry of the deposited coatings. The plasma deposition process was shown to produce polymerised coatings on the substrate surface with good retention of the precursor functionality.

### Coated Samples

FIG. 2a shows a representative carbon (C 1s) spectrum for polymerised acrylic acid based precursors. The C 1s spectrum shows both C—C chains and retention of COOH functionality. Some oxidation of the precursor was also observed, resulting in the presence of small quantities of C—O and C═O species. Investigation of the high resolution C1s spectra revealed very similar chemistry to that previously reported for acrylic acid derived plasma coatings. Compositional analysis for each sample is included in Table 4. FIG. 2b shows a C 1s spectrum for a PEG acrylate based coating, displaying good retention of glycol functionality. The carbon chemistry for these samples may be found in Table 6.

In addition to the polymerised solvent, all samples contained 1-2% nitrogen, arising from the quaternary ammonium salt. High-resolution spectra revealed that the quaternary ammonium structure was retained during the plasma deposition process. FIG. 2a shows a typical spectrum for polymerised salts in acrylic acid. The nitrogen (N 1s) core level shows a peak in the region of 398-404 eV. Fitting synthetic peaks to the core level required two overlapping peaks. The main peak at −402 eV is attributed to nitrogen in a quaternary ammonium structure. The second peak at ˜400 eV is attributed to a neutral NR₃ chemistry. The relative concentration of the quaternary ammonium salts was found to vary between 45 and 73% of the total N content, as is evident from Table 5 and 7.

TABLE 4
Chemical environment of carbon for quaternary
ammonium salts in acrylic acid

| | C—C | C—O | C═O | COOH |
|---|---|---|---|---|
| 1a | 69.6 | 10.7 | 3.1 | 16.7 |
| 1b | 70.9 | 12.1 | 4.1 | 12.9 |
| 1c | 69.9 | 9.6 | 3.5 | 17.1 |
| 1d | 72.1 | 6.4 | 2.6 | 18.9 |
| 1e | 70.9 | 10.2 | 3.5 | 15.5 |
| 1f | 72.0 | 7.3 | 2.6 | 18.2 |
| 1g | 73.3 | 10.5 | 3.5 | 12.8 |
| 1h | 72.1 | 6.8 | 2.6 | 18.6 |

TABLE 5
Chemical environment of nitrogen for quaternary
ammonium salts in acrylic acid

| | N (quat) | N |
|---|---|---|
| 1a | 67.0 | 33.0 |
| 1b | 69.0 | 31.0 |
| 1c | 62.5 | 37.5 |
| 1d | 55.7 | 44.3 |
| 1e | 59.7 | 40.3 |
| 1f | 53.1 | 46.9 |
| 1g | 59.5 | 40.5 |
| 1h | 72.9 | 27.1 |

TABLE 6
Chemical environment of carbon for quaternary ammonium salts
in PEG acrylate

| | C—C | C*—CO | C—O | C═O | COOC |
|---|---|---|---|---|---|
| 1i | 64.7 | 6.1 | 24.0 | 2.9 | 2.4 |
| 1j | 72.9 | 5.5 | 17.6 | 2.1 | 1.9 |

TABLE 7
Chemical environment of nitrogen for quaternary
ammonium salts in PEG acrylate

| | N (quat) | N |
|---|---|---|
| 1i | 48.5 | 51.6 |
| 1j | 44.7 | 55.3 |

### Wash Tests

Following deposition, samples were cut from the coated films and subjected to a variety of wash tests. Samples were washed in NaOH_{(aq)}-pH 12, Water-pH 7 and HCl_{(aq)}-pH 2.

In all cases, no nitrogen was lost during the washing process; all samples had between 1% and 2% nitrogen at the surface before and after washing. However, the relative concentration of quaternary ammonium salt did change as a function of the washing process. Table 8 contains representative data for a range of samples under different washing conditions.

Washing with either water or acid typically reduces the amount of N present as a quaternary ammonium (—NR₃⁺), the only exception being acid washing of cetyl pyridium chloride in acrylic acid. This indicates removal of free surfactant from the surface.

The sodium hydroxide wash was much more interesting, we have attributed this to deprotonation of the quaternary ammonium salt. In the case of cetalkonium chloride in acrylic acid, the —NR₃⁺ is entirely deprotonated to the —NR₂ when washed in sodium hydroxide (FIG. 2), indicating that the trapped surfactant is fully accessible to the applied wash solution. Deprotonation appear to be partially reversed when washed in acid. A similar effect is observed for cetalkonium chloride in PEG, except that deprotonation is fully reversed on washing in acid.

Cetyl pyridinium chloride in acrylic acid coatings is very stable to water washing, indicating good entrapment of the surfactant. On washing the coating with alkali, the —NR₃⁺ is partially deprotonated, indicating that only ca. 40% of the —NR₃⁺ is susceptible to alkali attack at the surface. This may be due to either the physical properties of the coating or the dissociation constants of the ammonium cation. The —NR₃⁺ reverts completely to —NR₂ on acid washing. A similar effect is observed for benzalkonium chloride in acrylic acid where it is partially converted to —NR₂ on alkali wash, with nearly full reversion to —NR₃⁺ on acid wash.

Washing also changed the carbon chemistry of the coatings. The acrylic acid based coatings were severely altered by the washing procedures employed. Again, the sodium hydroxide wash proved to be the most aggressive, with the COOH functionality completely disappearing in some samples. Data for the sodium hydroxide washed samples are included in Tables 9-11. Although not as severe, all washing procedures lead to a reduction in the COOH peak.

The PEG based coatings were less susceptible to damage from the washing treatments. The sodium hydroxide altered the chemistry of the nitrogen component, but had limited effect on the PEG polymer. Water washing also had little effect. However, the HCl wash did have a dramatic effect on the C—O functionality, with most of the C—O species disappearing, as is evident from Table 12.

TABLE 8
Nitrogen as quaternary ammonium with varying wash conditions

| | % N as Quaternary Ammonium | | | | |
|---|---|---|---|---|---|
| | | | | | NaOH |
| | | H₂O | HCl | NaOH | then |
| | Coated | wash | wash | wash | HCl wash |
| Cetalkonium chloride | 67.0 | 49.2 | 58.3 | 0 | 34.1 |
| in acrylic acid | | | | | |
| 0.4 kW, 25 μlmin⁻¹ | | | | | |
| Cetyl Pyridinium chloride | 53.1 | 52.6 | 57.2 | 20.1 | 51.9 |
| in acrylic acid | | | | | |
| 0.4 kW, 25 μlmin⁻¹ | | | | | |
| Benzalkonium chloride | 72.9 | 40.0 | 54.7 | 38.9 | 61.4 |
| in acrylic acid | | | | | |
| 0.4 kW, 25 μlmin⁻¹ | | | | | |
| Cetalkonium chloride | 44.7 | 40.1 | 48.4 | 0 | 46.6 |
| in PEG Methacrylate | | | | | |
| 0.4 kW, 25 μlmin⁻¹ | | | | | |

TABLE 9
Chemical environment of carbon for cetalkonium chloride
deposited in acrylic acid using various washing conditions

| Cetalkonium | | | | | | |
|---|---|---|---|---|---|---|
| chloride in | | | | | | |
| acrylic acid | | | | | | |
| 0.4 kW, | | | | | | |
| 25 μlmin⁻¹ | C—C | C*—C═O | C—O | C═O | C(O)OC | C(O)OH |
| coated | 72.1 | 0 | 6.4 | 2.6 | 0 | 18.9 |
| H₂O wash | 72.0 | 11.1 | 5.7 | 2.8 | 4.0 | 4.5 |
| NaOH wash | 84.3 | 6.0 | 3.5 | 3.5 | 2.3 | 3.9 |
| HCl wash | 68.9 | 12.3 | 6.9 | 2.6 | 1.6 | 7.7 |
| NaOH | 84.5 | 4.3 | 6.4 | 1.5 | 1.0 | 2.3 |
| then HCl | | | | | | |
| wash | | | | | | |

TABLE 10
Chemical environment of carbon for cetyl pyridinium chloride
deposited in acrylic acid using various washing conditions

| Cetyl | | | | | | |
|---|---|---|---|---|---|---|
| pyridinum | | | | | | |
| chloride in | | | | | | |
| acrylic acid | | | | | | |
| 0.4 kW, | | | | | | |
| 25 μlmin⁻¹ | C—C | C*—C═O | C—O | C═O | C(O)OC | C(O)OH |
| coated | 72.0 | 0 | 7.3 | 2.6 | 0 | 18.2 |
| H₂O wash | 77.8 | 8.6 | 5.2 | 1.9 | 2.6 | 3.9 |
| NaOH wash | 85.2 | 5.8 | 3.6 | 1.8 | 2.7 | 0.9 |
| HCl wash | 70.0 | 12.2 | 5.8 | 2.4 | 3.4 | 6.4 |
| NaOH then | 86.9 | 4.6 | 4.2 | 0.8 | 1.1 | 2.5 |
| HCl wash | | | | | | |

TABLE 11
Chemical environment of carbon for benzalkonium chloride
deposited in acrylic acid using various washing conditions

| Benzal- | | | | | | |
|---|---|---|---|---|---|---|
| konium | | | | | | |
| chloride in | | | | | | |
| acrylic acid | | | | | | |
| 0.4 kW, | | | | | | |
| 25 μlmin⁻¹ | C—C | C*—C═O | C—O | C═O | C(O)OC | C(O)OH |
| coated | 72.1 | 0 | 6.8 | 2.6 | 0 | 18.6 |
| H₂O wash | 77.1 | 8.6 | 5.6 | 2.0 | 3.4 | 3.3 |
| NaOH wash | 89.2 | 3.6 | 3.5 | 2.4 | 1.4 | 0 |
| HCl wash | 72.3 | 11.3 | 5.0 | 2.3 | 2.9 | 6.3 |
| NaOH then | 72.6 | 10.0 | 7.4 | 1.3 | 2.0 | 6.8 |
| HCl wash | | | | | | |

TABLE 12
Chemical environment of carbon for cetalkonium chloride
deposited in PEG acrylate using various washing conditions

| Cetalkonium chloride | | | | | |
|---|---|---|---|---|---|
| in PEG methacrylate | | | | | |
| 0.4 kW, 25 μlmin⁻¹ | C—C | C*—C═O | C—O | C═O | C(O)OC |
| coated | 72.9 | 5.5 | 17.6 | 2.1 | 1.9 |
| H₂O wash | 75.3 | 3.6 | 17.9 | 1.6 | 1.6 |
| NaOH wash | 76.7 | 2.5 | 17.2 | 1.4 | 2.1 |
| HCl wash | 83.4 | 3.2 | 1.1 | 1.6 | 1.7 |
| NaOH then HCl wash | 80.3 | 2.6 | 14.6 | 0.9 | 1.7 |

### Anti-Fungal Activity of Treated Polyester Fabrics

After 2 weeks of incubation, treated and untreated fabric specimens were entirely covered by microorganisms (growth rating=5) —as shown in FIG. 1. In general, fabric surface is a good support for microorganism adherence (i.e. the first step of a contamination process).

After 4 incubation weeks, moulds aggregated at the surface of fabric specimens in order to form a cell “skin”. Using a scalpel, this cell skin was removed and the surface of fabric was analysed by stereomicroscopy. No trace of spores and mycelium was detected between stitches of treated and untreated fabric. All fabric samples presented a clean surface after removing the mould skin, because polyester is not an appropriate nutrient source for microorganisms.

After scraping the sample surface for removing moulds, all samples were soaked in alcohol and allowed to air dry before proceeding to a second visual observation. Results clearly showed that 4 samples presented a colour change (pink colour) and Table 13. Both untreated samples as well as samples treated with cetalkonium showed a colour change after 4 weeks of microorganism attack, indicating degradation of the substrate had occurred. On the other hand, fabric samples treated with cetyl pyridinium and benzalkonium are very resistant to the treatment with microorganisms. No change of fabric texture and flexibility was observed.

TABLE 13
Results of microbial testing

| | Colour change |
|---|---|
| Sample | after treatment |
| Blank polyester fabric | Pink colour |
| Acrylic acid on polyester fabric | Pink colour |
| Cetalkonium chloride + acrylic acid on polyester | Pink colour |
| fabric | |
| Cetalkonium chloride + PEG methacrylate | Pink colour |
| on polyester fabric | |
| Cetyl pyridinium chloride + acrylic acid | No change |
| on polyester fabric | |
| Cetyl pyridinium chloride + PEG methacrylate | No change |
| on polyester fabric | |
| Benzalkonium chloride + acrylic acid | No change |
| on polyester fabric | |
| Benzalkonium chloride + PEG methacrylate | No change |
| on polyester fabric | |

The following description is intended to describe a selection of alternative plasma jet atmospheric plasma generating systems which may be used in the present invention.

FIG. 4 relates to a Single electrode design plasma jet system. This design consists of a tube (7), surrounded by a suitable dielectric material (8). The process gas enters an opening (6). A single electrode (5) is placed outside the tube and this is encased in a layer the dielectric material (8). The electrode is connected to a suitable power supply. No counter electrode is required. When power is applied, local electric fields form around the electrode. These interact with the gas within the tube and a plasma is formed, which exits through an aperture (9)

FIG. 5 relates to an alternative plasma jet electrode design. A single sharp electrode is housed within a plastic tube through which the aerosol and process gas flow. As power is applied to the needle electrode, an electric field forms and the process gas is ionised, as in the previous design. A 6 mm pipe is included at the exit of the plasma to maintain the laminar flow of the plasma gas. This acts to minimise entrainment of air, which would quench the plasma jet after it leaves the device. With this design it is possible to produce plasma jets using a range of process gases, to include helium, argon, oxygen, nitrogen, air and mixtures of said gases. This shows a metal electrode (12) housed within a suitable chamber (10). This chamber may be constructed from a suitable dielectric material such as polytetrafluoroethylene. The process gas and precursors enter into the chamber through one or more apertures (11) in the housing. As an electric potential is applied to the electrode, the process gas becomes ionised, and the resultant plasma is directed out through an opening (14). By adjusting the size and shape of the exit pipe (13), the size, shape and length of the plasma flame can be adjusted.

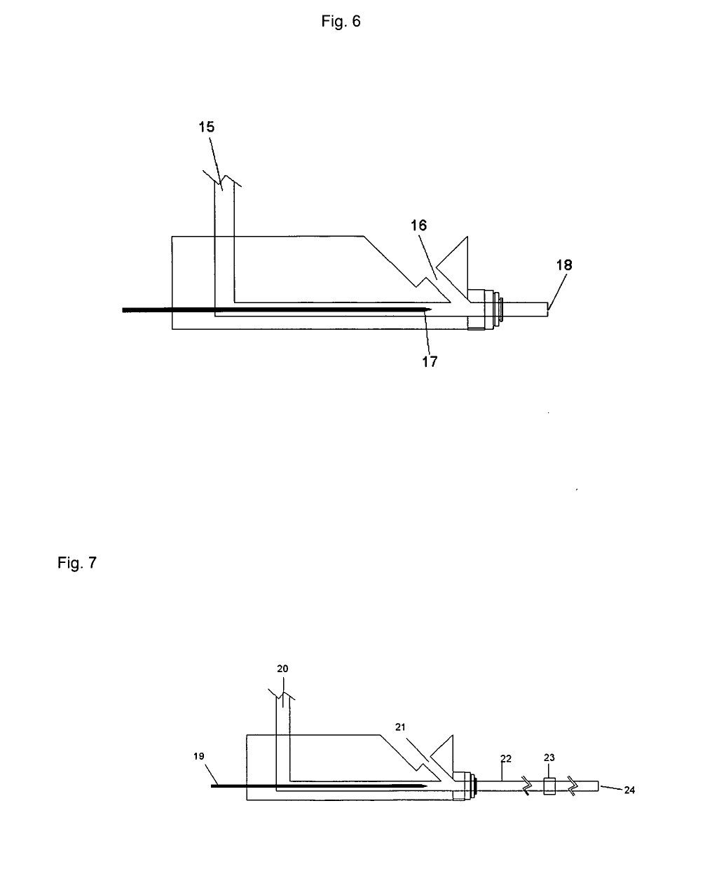

FIG. 6 depicts an alternative design in which the aerosol and process gas enter upstream (15) of the plasma. In an alternative design, the aerosol is introduced directly into the plasma. This is achieved by having a second gas entry point (16) located close to the tip of the electrode (17). The aerosol can be added directly at this point (16), with the main process gas still entering upstream of the plasma region (15). Alternatively, some (or all) of the process gas can also be added with the aerosol adjacent to the tip of the electrode. Using this setup, the plasma and precursor exit though a suitable opening (18).

FIG. 7 depicts a preferred device for the treatment of the inside of 3-D objects and or tubes and or conducting substrates has also been developed which generates long plasmas. As before, a powered electrode (19) interacts with a process gas (20) and aerosol (21) to produce a plasma. The length of the plasma can be extended by confining the plasma to a tube (22) as it leaves the device. As long as the plasma is confined within this tube, then the plasma is not quenched by interaction with the external atmosphere. In order to further extend the plasma length, conductive pieces (23) may be inserted into the tube. The resulting plasma may be extended over considerable distance before exiting through a suitable opening (24).

1. A method for forming an active material containing coating on a substrate, which method comprises the steps of:
i) introducing one or more gaseous or atomised liquid and/or solid coating-forming materials which undergo chemical bond forming reactions within a plasma environment and one or more active materials which substantially do not undergo chemical bond forming reactions within the plasma environment, into an atmospheric or low pressure non-thermal equilibrium plasma discharge and/or an excited gas stream resulting therefrom, and
ii) exposing the substrate to the resulting mixture of the one or more gaseous or atomised coating-forming materials and the one or more active materials which are deposited onto a surface of the substrate to form the coating.

2. A method in accordance with claim 1 wherein the coating-forming material is introduced into the plasma discharge by one or more atomisers.

3. A method in accordance with claim 1 wherein the active material is introduced into the plasma discharge through the same atomiser as the coating-forming material.

4. A method in accordance with claim 1 wherein the active material is introduced into the plasma discharge by way of a separate active material introducing means.

5. A method in accordance with claim 4 wherein the active material introducing means is an atomiser or in the case of powders is a compressed gas or gravity powder feeder.

6. A method in accordance with claim 1 wherein the substrate is passed through the plasma discharge and/or the excited gas stream resulting therefrom.

7. A method in accordance with claim 1 wherein the treatment of the substrate surface is undertaken away from the plasma discharge and/or the excited gas stream resulting therefrom.

8. A method in accordance with claim 1 wherein the active material comprises one or more anti-microbials, enzymes, proteins, DNA/RNA, aloe, vitamins, fragrances & flavours, agrochemicals and/or catalysts.

9. A method in accordance with claim 1 wherein the active material is an ingredient in a pharmaceutically active material, cosmeceutically active material, therapeutically active material or diagnostically active material.

10. A method in accordance with claim 1 wherein the active material is a therapeutically active material selected from one or more of antiacne agents, antibiotics, antiseptics, anti-fungals, anti-bacterials, anti-microbials, biocides, anti-inflammatories, astringents, hormones, anti-cancer agents, smoking cessation compositions, cardiovascular agents, histamine blockers, bronchodilators, analgesics, antiarrythmics, anti-histamines, alpha-I blockers, beta blockers, ACE inhibitors, diuretics, anti-aggregants, sedatives, tranquilizers, anti-convulsants, anti-coagulant agents, vitamins, anti-aging agents, agents for treating gastric and duodenal ulcers, anticellulites, proteolytic enzymes, healing factors and/or cell growth nutrients, and peptides.

11. A method in accordance with claim 10 wherein the active material is selected from one or more of penicillins, cephalosporins, tetracyclines, macrolides, epinephrine, amphetamines, aspirin, acetominophen, barbiturates, catecholamines, benzodiazepine, thiopental, codeine, morphine, procaine, lidocaine, benzocaine, sulphonamides, ticonazole, perbuterol, furosamide, prazosin, prostaglandins, salbutamol, indomethicane, diclofenac, glafenine, dipyridamole, theophylline and retinal.

12. A method in accordance with claim 1 wherein the active material is selected from one or more of a UV screening material, an anti-oxidant, a flame retardant, an antibiotic, an antibacterial, an anti-fungal, a cosmetic, a cleanser, a growth factor, aloe, vitamins, fragrances & flavours, agrochemicals and catalysts.

13. A method in accordance with claim 1 wherein the active material is selected from one or more absorbents, anti-caking materials, anti-oxidants, anti-static materials, astringents, binders, buffering materials, bulking materials, chelating materials, colorants, cosmetic astringents, cosmetic biocides, deodorant materials, emollients, external analgesics, film formers, flavouring materials, fragrance ingredients, humectants, lytic materials, moisturizing materials, occlusivity enhancers, opacifying materials, oxidizing and reducing materials, penetration enhancers, pesticides, plasticizers, preservatives, skin bleaching materials, skin conditioning materials, skin protectants, slip modifiers, solubilizing materials, solvents, sunscreen materials, surface modifiers, surfactants emulsifying materials, suspending materials, thickening materials, viscosity controlling materials including increasing or decreasing materials, and UV light absorbers.

14. A method in accordance with claim 1 wherein the substrate is plasma pre-treated and/or post-treated.

15. A method in accordance with claim 1 wherein a plurality of coatings containing the active materials material are applied onto the substrate.

16. A method in accordance with claim 1 wherein the active material is a pesticidally, herbicidally and/or fungicidally active material.

17. A method in accordance with claim 14 wherein the plasma post-treatment comprises the application of an additional coating that is free of active materials as a topcoat.

18. A product comprising a substrate coated with an active material containing coating obtainable by introducing one or more gaseous or atomised liquid and/or solid coating-forming materials which undergo chemical bond forming reactions within a plasma environment and one or more active materials which substantially do not undergo chemical bond forming reactions within the plasma environment, into an atmospheric or low pressure plasma discharge and/or an excited gas stream resulting therefrom, and exposing the substrate to the resulting mixture of the one or more gaseous or atomised coating-forming materials and the one or more active materials, wherein the substrate is not a wipe, cloth or sponge for household care or depilatory care or a water soluble household cleaning unit dose product.

19. (canceled)

20. A product in accordance with claim 18 wherein the substrate is a textile material other than a wipe, cloth or sponge for household care or depilatory care.

21. A coated substrate obtainable by the method of claim 1.

22-25. (canceled)

26. A product in accordance with claim 18 wherein the substrate is a pill, tablet, capsule and/or powder.

27. A coated substrate product in accordance with claim 18 wherein the substrate is a wound dressing.

28. A product in accordance with claim 18 comprising a pharmaceutically active material ingredient entrapped in a physiologically and/or pharmaceutically acceptable coating on a physiologically and/or pharmaceutically acceptable carrier.

29-33. (canceled)

34. A method in accordance with claim 1 wherein the coating is applied by plasma enhanced chemical vapour deposition.

35. A method in accordance with claim 1 wherein the substrate is a polyolefin, a polycarbonate, a polyurethane, a polyvinylchloride, a polyester, a terephthalate, a polymethacrylate, a polymer of hydroxyethylmethacrylate, a polyepoxide, a polysulphone, a polyphenylene, a polyetherketone, a polyimide, a polyamide, a polystyrene, a polyfluoroalkane, a polysiloxane, a phenolic, epoxy or melamine-formaldehyde resin, and blends and copolymers thereof.

36. A method in accordance with claim 1 wherein the substrate is a metallic thin film or a flat web made from film, paper, fabric, non-woven, metallic foil, powder and/or moulded or engineered components.

37. A method in accordance with claim 1 wherein the substrate is a powder comprising metals, metal oxides, silica and silicates, carbon, organic powdered substrates, mineral fillers mica conductive fillers, TiO₂ nanoparticles, metal oxides graphite, phosphorus particles, pigments, metalloid oxides, mixed oxides, organometallic oxides, organometalloid oxides, organomixed oxide resins and/or organic resins, sodium carbonate, potassium nitrate, silicon metal particles, silicone rubber crumbs, siloxane resins, siloxane waxes, and/or organic rubber crumb.

38. A method in accordance with claim 1 wherein the substrate is in the form of synthetic fibres, natural fibres, woven fibres, non-woven fibres, powders, siloxanes, fabrics, human-based tissue based dressings, cellulosic materials, or blends of organic polymeric materials.
